(19) United States
(12) Patent Application Publication
(10) Pub. No.: US 2025/0167091 A1
(43) Pub. Date: May 22, 2025

(54) CORE SUBSTRATE AND INTERPOSER

(71) Applicant: NGK INSULATORS, LTD., Nagoya-shi (JP)

(72) Inventors: Yoshitsugu WAKAZONO, Nagoya-shi (JP); Makoto TANI, Inazawa-shi (JP); Takahiro ANDO, Nagoya-shi (JP); Asami NATORI, Nagoya-shi (JP)

(21) Appl. No.: 19/023,701

(22) Filed: Jan. 16, 2025

Related U.S. Application Data
(63) Continuation of application No. PCT/JP2022/029114, filed on Jul. 28, 2022.

(51) Int. Cl. H01L 23/498; H01F 27/24; H01L 23/15; H05K 1/11; H05K 1/16; H10D 1/20

(52) U.S. Cl. CPC H01L 23/49827; H01F 27/24; H05K 1/115; H05K 1/165; H10D 1/20; H01L 23/15; H01L 23/49894; H05K 2201/10378

(57) ABSTRACT

A core substrate is a core substrate with a built-in inductor for constructing an interposer to which a semiconductor element is mounted. The core substrate includes a ceramic substrate, a conductor portion, and a magnetic material portion. The ceramic substrate has a first surface, a second surface opposite the first surface in a thickness direction, and a through hole between the first surface and the second surface. The conductor portion extends through the through hole, and is made of a sintered material including sintered metal. The magnetic material portion surrounds the conductor portion within the through hole, and is made of ceramics. The ceramic substrate and the magnetic material portion are inorganically bonded together, and the magnetic material portion and the conductor portion are inorganically bonded together.

### CROSS-REFERENCE TO RELATED APPLICATION

This application is a continuation application of PCT/JP2022/029114, filed on Jul. 28, 2022, the entire contents of which are incorporated herein by reference.

### BACKGROUND OF THE INVENTION

### Field of the Invention

The present invention relates to core substrates and interposers and, in particular, to a core substrate with a built-in inductor for constructing an interposer to which a semiconductor element is mounted.

### Description of the Background Art

According to Japanese Patent Application Laid-Open No. 2019-179792, an interposer is disposed between a semiconductor element and a motherboard in a semiconductor device. The interposer and each of the semiconductor element and the motherboard are connected using solder balls. A multilayer wiring printed board is shown as the interposer, and includes a core substrate, three conductor circuit layers stacked over the core substrate to face the semiconductor element, and three conductor circuit layers stacked over the core substrate to face the motherboard. On a side of the interposer where the semiconductor element is mounted, a wiring dimension is reduced in stages by passing through the three conductor circuit layers.

Efficient power management is sometimes required for a semiconductor element for an integrated circuit (IC), for example. A supply voltage to each of a plurality of computing cores of a processor chip (the semiconductor element) is typically controlled by a voltage regulator in response to an amount of computation of a processor and the like. A switch, a capacitor, and an inductor are normally required to construct the voltage regulator. The switch, the capacitor, and the inductor are required for each of the computing cores to control the supply voltage for each of the computing cores. In particular, the inductor is difficult to be built in the semiconductor element, and thus is normally prepared separately from the semiconductor element. Use of a magnetic material is proposed to secure a sufficient inductance while suppressing a footprint for the inductor.

US Patent Application Publication No. 2019/0279806 discloses a package substrate (a kind of interposer herein) disposed between a die (the semiconductor element) and a board (the motherboard). An inductor for the above-mentioned purpose is built in the package substrate. Specifically, the package substrate includes a substrate core, a conductive through hole through the substrate core, and a magnetic sheath around the conductive through hole. The magnetic sheath may include magnetic particles. The substrate core may be any substrate on which build-up layers (the conductor circuit layers) are formed. An organic material is shown as an example of the core substrate.

WO 2007/129526 discloses a core substrate in which an inductor is disposed. As a method for manufacturing the inductor, a through hole is formed in an axial direction of a longitudinally extending magnetic body, and a conductor is formed on an inner surface of the through hole by metal plating. The conductor is formed to be hollow to release a stress caused by a difference in thermal expansion between the conductor and the magnetic body. As a method for embedding the inductor in the substrate, a through hole is formed in the substrate, the inductor is inserted into the through hole, and a space between the inductor and the substrate is filled with a resin.

In the above, some features related to the patent documents, namely, Japanese Patent Application Laid-Open No. 2019-179792, US Patent Application Publication No. 2019/0279806 and WO 2007/129526, have been outlined.

A plurality of computing cores have recently been mounted to a die (the semiconductor element) to be joined to an interposer. In particular, a high-performance processor, such as that for a data server, includes many computing cores to increase computational processing capability, so that the number of computing cores per the area of the die is large, and the area of the die per computing core is small. To accommodate this, a high-density inductor having a larger inductance per unit area of the interposer is required.

US Patent Application Publication No. 2019/0279806 described above shows an example in which the substrate core mainly made of the organic material includes the conductive through hole (a conductor portion) and the magnetic sheath (a magnetic material portion) formed around the conductor portion and including the magnetic particles. In this case, the magnetic material portion is required to be formed at or below a heat resistant temperature of the organic material for the substrate core. As a typical technique satisfying the requirement, there is a technique of solidifying a resin in which the magnetic particles are dispersed. When the magnetic material portion includes the magnetic particles dispersed in the resin, however, a high permeability is less likely to be secured due to limitation of a filling factor of the magnetic particles (a proportion of the magnetic particles per volume). While the size of the inductor built in the interposer is required to be reduced in response to the above-mentioned densification of the interposer, a sufficient inductance is less likely to be secured when a dimension of each inductor is reduced by densification as permeability of the magnetic material portion is less likely to be increased as described above.

In WO 2007/129526 described above, the space between the inductor and the substrate is filled with the resin. A resin material generally has a lower heat resistance than an inorganic material, so that the core substrate sometimes has a lower heat resistance due to use of the resin. The conductor (conductor portion) of the inductor is made of a plating film. In other words, plating is used as a method for forming the conductor portion. Due to this, variation of electrical characteristics (in particular, conductivity) of the conductor portion is likely to increase.

### SUMMARY

The aspects described below have been conceived to solve a problem as described above, and it is an object of them to provide a core substrate with a built-in inductor for constructing an interposer to which a semiconductor element is mounted that includes the built-in inductor having a large inductance per unit area of the core substrate and has a high heat resistance and stable electrical characteristics.

A first aspect is a core substrate with a built-in inductor for constructing an interposer to which a semiconductor element is mounted. The core substrate includes a ceramic substrate, a conductor portion, and a magnetic material portion. The ceramic substrate has a first surface, a second surface opposite the first surface in a thickness direction, and a through hole between the first surface and the second surface. The conductor portion extends through the through hole, and is made of a sintered material including sintered metal. The magnetic material portion surrounds the conductor portion within the through hole, and is made of ceramics. The ceramic substrate and the magnetic material portion are inorganically bonded together, and the magnetic material portion and the conductor portion are inorganically bonded together.

A second aspect is the core substrate according to the first aspect, wherein the conductor portion is a non-hollow body.

A third aspect is the core substrate according to the first or the second aspect, further including a terminal. The terminal faces each of the conductor portion and the magnetic material portion in the thickness direction, and is made of a sintered material including sintered metal. The terminal and each of the conductor portion and the magnetic material portion are inorganically bonded together.

A fourth aspect is the core substrate according to any one of the first to the third aspects, wherein the ceramic substrate and the magnetic material portion are bonded together without an organic material interposed therebetween, and the magnetic material portion and the conductor portion are bonded together without an organic material interposed therebetween.

A fifth aspect is the core substrate according to any one of the first to the fourth aspects, wherein the ceramic substrate and the magnetic material portion are sintered together, and the magnetic material portion and the conductor portion are sintered together.

A sixth aspect is the core substrate according to any one of the first to the fifth aspects, wherein the magnetic material portion has at least one of a protruding structure toward the ceramic substrate and a step structure facing the ceramic substrate.

A seventh aspect is the core substrate according to any one of the first to the sixth aspects, wherein the conductor portion has a protruding structure toward the magnetic material portion.

An eighth aspect is an interposer including: the core substrate according to any one of the first to the seventh aspects; and a wiring portion including a connecting via having a bottom surface connected to the conductor portion of the core substrate. The bottom surface of the connecting via is separated from the magnetic material portion and the ceramic substrate.

A ninth aspect is the interposer according to the eighth aspect, further including an insulator layer having a via hole in which the connecting via is disposed. The insulator layer separates the wiring portion and each of the magnetic material portion and the ceramic substrate of the core substrate.

A tenth aspect is the interposer according to the ninth aspect, wherein the via hole of the insulator layer is tapered toward the conductor portion.

An eleventh aspect is the interposer according to the ninth or the tenth aspect, wherein the insulator layer contains organic matter.

A twelfth aspect is the interposer according to any one of the eighth to the eleventh aspects, wherein the wiring portion is a plating layer.

A thirteenth aspect is an interposer including: the core substrate according to any one of the first to the seventh aspects; an electrode pad connected to the conductor portion of the core substrate; and a wiring portion including a connecting via having a bottom surface connected to the electrode pad. The bottom surface of the connecting via is separated from the magnetic material portion and the ceramic substrate.

A fourteenth aspect is the interposer according to the thirteenth aspect, wherein the electrode pad has a portion covering the magnetic material portion.

A fifteenth aspect is the interposer according to the thirteenth or the fourteenth aspect, wherein the electrode pad contains silver.

A sixteenth aspect is the interposer according to any one of the thirteenth to the fifteenth aspects, wherein the electrode pad is made of a sintered material including sintered metal.

A seventeenth aspect is the interposer according to any one of the thirteenth to the sixteenth aspects, wherein the wiring portion is a plating layer.

According to the above-mentioned first aspect, the magnetic material portion is not made of a resin in which magnetic particles are dispersed, but is made of ceramics. By densely sintering the ceramics, the magnetic material portion can have a sufficiently high permeability. An inductor having a large inductance per unit area can thereby be built in the core substrate. The ceramic substrate and the magnetic material portion are inorganically bonded together. This eliminates the need for use of a resin to bond the ceramic substrate and the magnetic material portion together. Reduction in heat resistance of the core substrate due to the use of the resin is thereby avoided. The conductor portion is made of the sintered material including the sintered metal. Variation of electrical characteristics of the conductor portion can thereby be suppressed compared with a case where the conductor portion is a plating film. Electrical characteristics of the core substrate can thus be stabilized. In view of the foregoing, the core substrate can include the built-in inductor having a large inductance per unit area, and have a high heat resistance and stable electrical characteristics.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view schematically showing a configuration of electronic equipment in Embodiment 1.

FIG. 2 is a cross-sectional view illustrating electronic equipment in a modification of FIG. 1.

FIG. 3 is a schematic diagram illustrating a configuration of inductors built in a core substrate in Embodiment 1 of the present invention.

FIG. 4 is a circuit diagram illustrating an example of electrical connection between a first inductor and a second inductor illustrated in FIG. 3.

FIG. 5 is a diagram schematically showing a configuration of the core substrate in Embodiment 1, and is a partial cross-sectional view taken along the line V-V of FIG. 6.

FIG. 6 is a partial cross-sectional view taken along the line VI-VI of FIG. 5.

FIG. 7 is a partial cross-sectional view illustrating a configuration of a core substrate in a comparative example.

FIG. 8 is a partial cross-sectional view schematically showing a configuration of a core substrate in Embodiment 2.

FIG. 9 is a partial cross-sectional view schematically showing a configuration of a core substrate in Embodiment 3.

FIG. 10 is a partial cross-sectional view schematically showing a configuration of a core substrate in Embodiment 4.

FIG. 11 is a partial cross-sectional view schematically showing a configuration of a core substrate in Embodiment 5.

FIG. 12 is a partial cross-sectional view schematically showing a configuration of a core substrate in Embodiment 6.

FIG. 13 is a partial cross-sectional view schematically showing a configuration of a core substrate in Embodiment 7.

FIG. 14 is a partial cross-sectional view schematically showing a configuration of a core substrate in Embodiment 8.

FIG. 15 is a partial cross-sectional view schematically showing a configuration of a core substrate in Embodiment 9.

FIG. 16 is a partial cross-sectional view schematically showing a configuration of a core substrate in Embodiment 10.

FIG. 17 is a diagram schematically showing a configuration of an interposer in Embodiment 11, and is a partial cross-sectional view taken along the line XVII-XVII of FIG. 18.

FIG. 18 is a partial plan view schematically showing a configuration of a second surface of the interposer in FIG. 17.

FIG. 19 is a diagram schematically showing a configuration of an interposer in Embodiment 12, and is a partial cross-sectional view taken along the line XIX-XIX of FIG. 20.

FIG. 20 is a partial plan view schematically showing a configuration of a second surface of the interposer in FIG. 19.

FIG. 21 is a partial plan view schematically showing a configuration of a core substrate in Embodiment 13.

FIG. 22 is a partial cross-sectional view taken along the line XXII-XXII of FIG. 21.

FIG. 23 is a partial plan view schematically showing a configuration of a core substrate in Embodiment 14.

FIG. 24 is a partial cross-sectional view taken along the line XXIV-XXIV of FIG. 23.

FIG. 25 is a partial plan view illustrating a modification of FIG. 23.

FIG. 26 is a partial cross-sectional view schematically showing a configuration of a core substrate in Embodiment 15.

FIG. 27 is a partial enlarged view of FIG. 26.

FIG. 28 is a perspective view of FIG. 27.

FIG. 29 is a modification of FIG. 27.

FIG. 30 is a perspective view of FIG. 29.

FIG. 31 is a partial cross-sectional view schematically showing a configuration of a core substrate in Embodiment 16.

FIG. 32 is a partial enlarged view of FIG. 31.

FIG. 33 is a partial perspective view of FIG. 32.

### DESCRIPTION OF THE PREFERRED EMBODIMENTS

Embodiments of the present invention will be described below based on the drawings.

### Embodiment 1

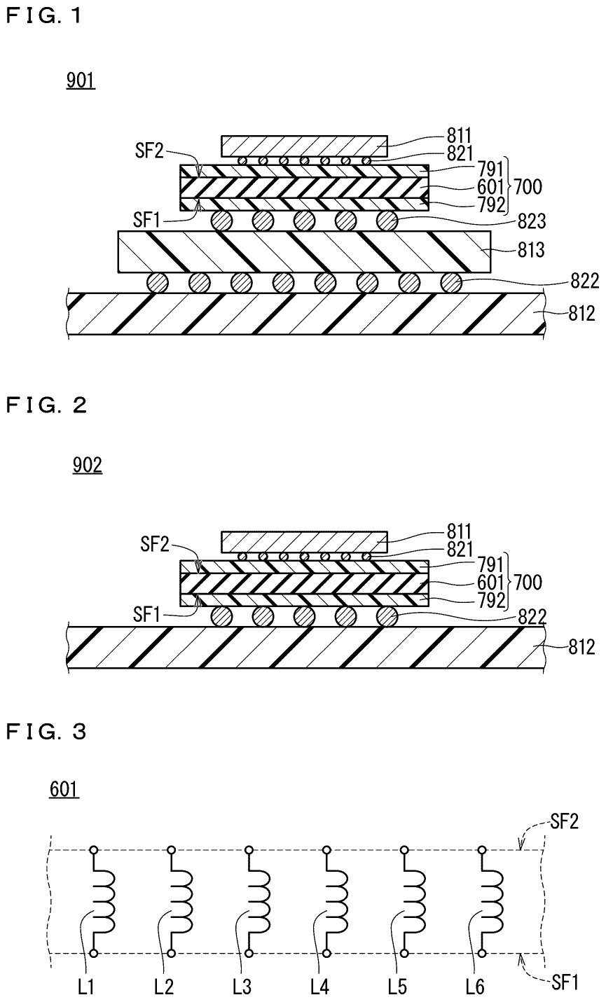

FIG. 1 is a cross-sectional view schematically showing a configuration of electronic equipment 901 in Embodiment 1. The electronic equipment 901 includes an interposer 700, a semiconductor element 811 (die), a motherboard 812, and a package substrate 813. The interposer 700 includes a core substrate 601, a wiring layer 791, and a wiring layer 792.

The wiring layer 792 and the wiring layer 791 are respectively stacked over one surface and the other surface (specifically, directly or indirectly over a first surface SF1 and a second surface SF2 described below) of the core substrate 601. The wiring layer 791 and the wiring layer 792 may be stacked over the core substrate 601 by build-up or sputtering, or may be joined as separate wiring boards.

The wiring layer 791 is preferably a multilayer wiring layer configured to have a wiring dimension (e.g., a line and space (US) dimension) reduced from a side facing the core substrate 601 to a side facing the semiconductor element 811. The interposer 700 to which the semiconductor element 811 having a small terminal pitch can be mounted can thereby be constructed even if a wiring (US) dimension of the core substrate 601 is not so fine. Specifically, the wiring layer 791 may be a stack of a normal wiring layer facing the core substrate 601 and a fine wiring layer facing the semiconductor element 811.

The normal wiring layer may be formed by providing a wiring structure to a plate-like organic material (e.g., an epoxy-based member) or inorganic material (e.g., a low temperature co-fired ceramics (LTCC) material or a non-magnetic ferrite material). Cu plating is used to form the wiring structure to the organic material, for example. To form the wiring structure to the inorganic material, the wiring structure is formed by firing of Ag (silver), AgPd (silver palladium), or Cu (copper) simultaneously with formation of the inorganic material in a firing step.

The fine wiring layer is preferably formed by providing a wiring structure to a plate-like organic material (e.g., an epoxy-based or a polyimide-based member) in terms of ease of formation of fine wiring. Cu plating is used to form the wiring structure to the organic material, for example.

The semiconductor element 811 is mounted to the wiring layer 791 of the interposer 700. The semiconductor element 811 is connected to the wiring layer 791 of the interposer 700 by solder balls 821, for example. The semiconductor element 811 may be an integrated circuit (IC) chip. In particular, when the IC chip is a processor chip including a plurality of computing cores, the above-mentioned voltage regulator can be constructed using an inductor described below.

The interposer 700 is mounted to the package substrate 813 by joining the wiring layer 792 to the package substrate 813. The joining is achieved by solder balls 823, for example. The package substrate 813 is mounted to the motherboard 812, for example, by joining using solder balls 822.

According to the foregoing, an element side (a side facing the semiconductor element 811) of the interposer 700 is constructed by the wiring layer 791, and a substrate side (a side facing the package substrate 813 and the motherboard 812) of the interposer 700 is constructed by the wiring layer 792. A plurality of terminals (not illustrated) are provided to each of the element side and the substrate side of the interposer 700. A terminal pitch on the element side may be smaller than a terminal pitch on the substrate side, and, in this case, the interposer 700 has a function of transforming the terminal pitch. As a modification, either or both of the wiring layer 791 and the wiring layer 792 may be omitted in some applications of the interposer.

FIG. 2 is a cross-sectional view illustrating electronic equipment 902 in a modification of the electronic equipment 901 (FIG. 1). In the electronic equipment 902, the interposer 700 is joined to the motherboard 812 without the package substrate 813 (FIG. 1) interposed therebetween, and the joining is achieved by the solder balls 822, for example.

FIG. 3 is a schematic diagram illustrating a configuration of inductors built in the core substrate 601 in Embodiment 1 of the present invention. In the core substrate 601, a plurality of inductors L1 and L2 are built, inductors L3 to L6 and the like may further be built, and any number of inductors may be built. While a configuration of the inductors L1 and L2 will be described in detail below, the inductors L3 to L6 and the like may have a similar configuration.

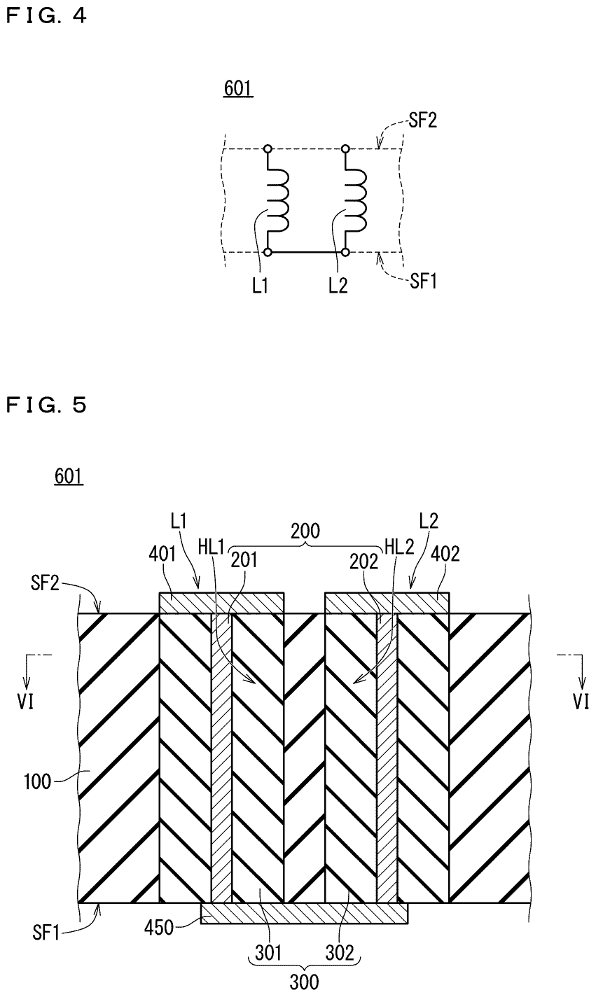

FIG. 4 is a circuit diagram illustrating an example of electrical connection between the inductors L1 and L2 illustrated in FIG. 3. In the present embodiment, the inductors L1 and L2 are connected in series to constitute an inductor having a combined inductance larger than an inductance of each of the inductors L1 and L2, and opposite ends of the inductor are arranged on the second surface SF2 to face the semiconductor element 811 (FIG. 1). The inductor having a sufficiently large inductance can thereby easily be connected to the semiconductor element 811. Electrical connection between the plurality of inductors built in the core substrate is not limited to that illustrated in FIG. 4, and may be designed as appropriate according to the application of the core substrate. A series structure of any number of inductors, a parallel structure of any number of inductors, or a combination thereof may thus be constructed.

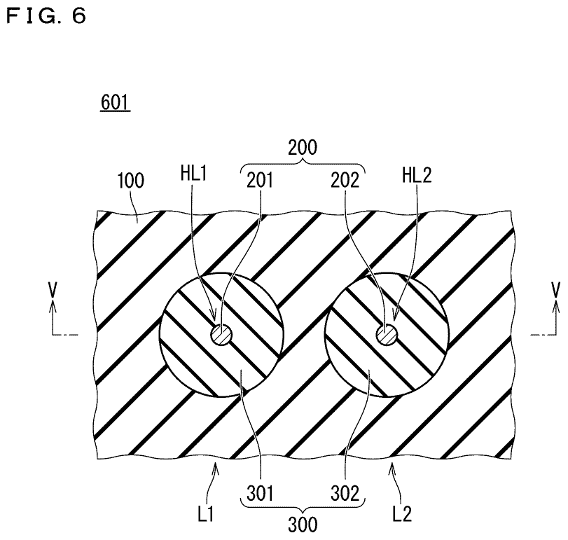

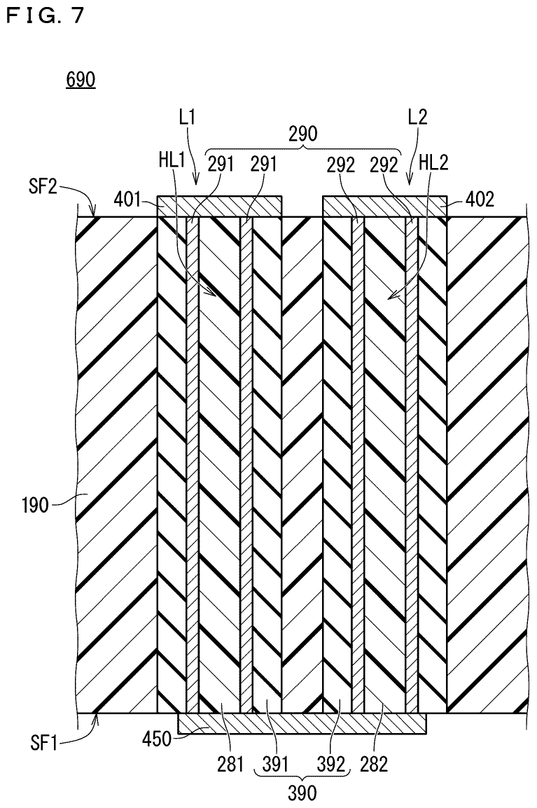

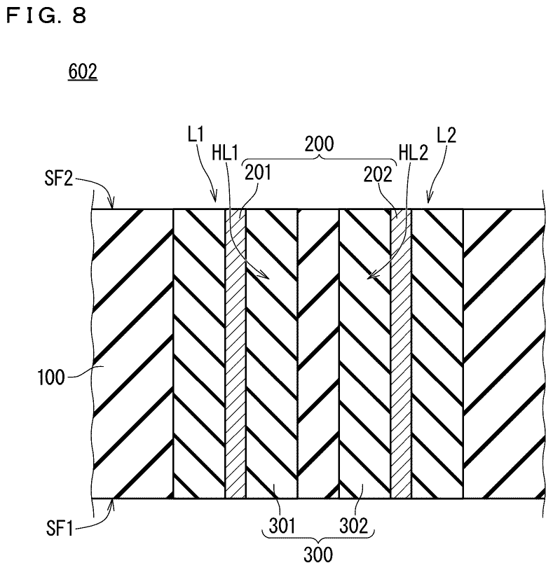

FIG. 5 is a diagram schematically showing a configuration of the core substrate 601 in Embodiment 1 of the present invention, and is a partial cross-sectional view taken along the line V-V of FIG. 6. FIG. 6 is a partial cross-sectional view taken along the line VI-VI of FIG. 5. As described above, the core substrate 601 is for constructing the interposer 700, and the inductors L1 and L2 are built in the core substrate 601. The core substrate 601 includes a ceramic substrate 100, a first conductor portion 201, a second conductor portion 202, a first magnetic material portion 301, a second magnetic material portion 302, an interconnecting portion 450 (a terminal), an electrode portion 401 (a terminal), and an electrode portion 402 (a terminal). The first conductor portion 201 and the second conductor portion 202 are also generically referred to as a conductor portion 200. The first magnetic material portion 301 and the second magnetic material portion 302 are also generically referred to as a magnetic material portion 300.

The ceramic substrate 100 has the first surface SF1 and the second surface SF2 opposite the first surface SF1 in a thickness direction. The ceramic substrate 100 is a substrate made of a ceramic sintered body. The ceramic sintered body does not substantially contain an organic component, and may contain a glass component. In other words, the ceramic substrate 100 may be made of glass ceramics. The ceramic substrate 100 is desirably made of LTCC. LTCC is ceramics that can be sintered at approximately 900° C. or less, and can be sintered at a temperature sufficiently lower than a melting point of Ag, AgPd, or Cu, so that LTCC can be sintered simultaneously with a built-in conductor containing Ag, AgPd, or Cu as a main component and having a low electrical resistance. The ceramic substrate 100 has a first through hole HL1 and a second through hole HL2 between the first surface SF1 and the second surface SF2. The ceramic substrate 100 preferably has a coefficient of thermal expansion of 4 ppm/° C. or more and 16 ppm/° C. or less. The ceramic substrate 100 preferably has a relative permittivity of 8 or less and a dissipation factor of 0.01 or less at 1 GHz.

The first conductor portion 201 and the second conductor portion 202 respectively extend through the first through hole HL1 and the second through hole HL2. The conductor portion 200 is a non-hollow body. In other words, the conductor portion 200 does not have a hollow interior. The conductor portion 200 is made of a sintered material including sintered metal. The sintered metal includes at least one of Ag, AgPd, and Cu, for example. The sintered material for the conductor portion 200 may include a ceramic material as a material having a lower conductivity than the sintered metal to the extent that its function as electrical wiring is maintained. A proportion of the ceramic material to the sintered metal is preferably 5 vol % or more and 30 vol % or less. The material for the conductor portion 200 includes the ceramic material, so that bonding between the conductor portion 200 and the magnetic material portion 300 can be enhanced. The ceramic material preferably has a particle size of 0.5 μm or more and 10 μm or less. Examples of the ceramic material include alumina, zirconia, magnesium oxide, and titanium oxide.

The first magnetic material portion 301 surrounds the first conductor portion 201 within the first through hole HL1. The second magnetic material portion 302 surrounds the second conductor portion 202 within the second through hole HL2. The first magnetic material portion 301 and the second magnetic material portion 302 may respectively be in direct contact with the first conductor portion 201 and the second conductor portion 202. The magnetic material portion 300 may have a circular inner edge and a circular outer edge in cross section (FIG. 6) perpendicular to the thickness direction. The inner edge and the outer edge may have another shape in place of the circular shape, and may have an elliptical shape or a polygonal shape, such as a quadrilateral shape, for example. Corners of the polygonal shape may be chamfered. Similarly, the first through hole HL1, the second through hole HL2, and the conductor portion 200 may each have another shape in cross section in place of the circular shape as illustrated in FIG. 6.

The magnetic material portion 300 is made of ceramics (a ceramic sintered body), and does not contain an organic component. To reduce the volume of the inductor, a magnetic material for the magnetic material portion 300 desirably has a high permeability, and the magnetic material portion 300 preferably has a compactness of 70% or more. To reduce an electrical loss of the inductor, the magnetic material for the magnetic material portion 300 is desirably a soft magnetic material having a small magnetic loss at a high frequency, and is desirably a soft magnetic material having a magnetic loss tangent of 0.1 or less at a frequency of 100 MHz, for example. To reduce a magnetic loss at a high frequency, the magnetic material for the magnetic material portion 300 desirably has a high volume electrical resistivity, and, specifically, is desirably an electrical insulator. The magnetic material portion 300 is preferably made of a ferrite-based material, a crystalline structure of the material is preferably a spinel structure in terms of ease of manufacture, Ni—Zn-based ferrite or Ni—Zn—Cu-based ferrite is used, for example, and the crystalline structure of the material is preferably a hexagonal structure having a c-axis orientation along the thickness direction (a vertical direction in FIG. 5) in terms of a high permeability.

A method for manufacturing the core substrate 601 includes a firing step. In the firing step, the conductor portion 200 (the first conductor portion 201 and the second conductor portion 202) and the magnetic material portion 300 (the first magnetic material portion 301 and the second magnetic material portion 302) are fired simultaneously with the ceramic substrate 100. An inorganic material for the conductor portion 200 and an inorganic material for the magnetic material portion 300 are thus bonded together without an organic material interposed therebetween. In other words, the conductor portion 200 and the magnetic material portion 300 are inorganically bonded together. Specifically, the conductor portion 200 and the magnetic material portion 300 are sintered together. Similarly, the inorganic material for the magnetic material portion 300 and an inorganic material for the ceramic substrate 100 are bonded together without an organic material interposed therebetween. In other words, the magnetic material portion 300 and the ceramic substrate 100 are inorganically bonded together. Specifically, the magnetic material portion 300 and the ceramic substrate 100 are sintered together.

The interconnecting portion 450 electrically connects one end of the first conductor portion 201 and one end of the second conductor portion 202 on the first surface SF1 of the ceramic substrate 100. On the second surface SF2 of the ceramic substrate 100, the electrode portion 401 is connected to the other end of the first conductor portion 201, and the electrode portion 402 is connected to the other end of the second conductor portion 202. The electrode portion 401 and the electrode portion 402 are away from each other. Thus, the one end of the first conductor portion 201 and the one end of the second conductor portion 202 are electrically connected to each other, and the other end of the first conductor portion 201 and the other end of the second conductor portion 202 are electrically separated from each other. A circuit illustrated in FIG. 4 is thereby constructed.

The electrode portion 401 faces each of the first conductor portion 201 and the first magnetic material portion 301 in the thickness direction (vertical direction in FIG. 5). The electrode portion 402 faces each of the second conductor portion 202 and the second magnetic material portion 302 in the thickness direction (vertical direction in FIG. 5). The interconnecting portion 450 faces each of the first conductor portion 201, the second conductor portion 202, the first magnetic material portion 301, and the second magnetic material portion 302 in the thickness direction (vertical direction in FIG. 5).

At least one of (preferably each of) the electrode portion 401, the electrode portion 402, and the interconnecting portion 450 is preferably a terminal made of a sintered material including sintered metal, and the sintered material may contain a small amount of glass component in addition to the sintered metal. The sintered metal contains Ag, AgPd, or Cu as a main component, for example. The electrode portion 401 and each of the first conductor portion 201 and the first magnetic material portion 301 are preferably inorganically bonded together. The electrode portion 402 and each of the second conductor portion 202 and the second magnetic material portion 302 are preferably inorganically bonded together. The interconnecting portion 450 and each of the first conductor portion 201, the second conductor portion 202, the first magnetic material portion 301 and the second magnetic material portion 302 are preferably inorganically bonded together.

A design example of the core substrate 601 (FIGS. 5 and 6) will be described below. The ceramic substrate 100 has a square shape with sides of 50 mm in an in-plane direction, and has a dimension of 550 μm in the thickness direction. The plurality of through holes (the first through hole HL1, the second through hole HL2, and the like) are arranged at a pitch of 450 μm. The ceramic substrate 100 is made of an LTCC material containing a Ba—Si—Al—O element as a main component or glass alumina, for example. The magnetic material portion 300 (FIG. 6) has an outer diameter of 350 μm and an inner diameter of 100 μm. The conductor portion 200 has an outer diameter of 100 μm. The conductor portion 200 is formed by sintering of Ag or AgPd powder. The magnetic material portion 300 is made of a ferrite sintered body, and assume that relative permeability thereof is estimated to be 16. In this case, a single inductor (e.g., the inductor L1) has an inductance of approximately 2 nH at 140 MHz according to estimates of the inventors.

FIG. 7 is a partial cross-sectional view illustrating a configuration of a core substrate 690 in a comparative example. In the core substrate 690, the first through hole HL1 and the second through hole are formed in a resin substrate 190 made of a glass epoxy resin. A first magnetic material portion 391 and a first conductor portion 291 are formed in order over a side wall of the first through hole HL1, and the first conductor portion 291 has a hollow structure filled with a resin material 281. Similarly, a second magnetic material portion 392 and a second conductor portion 292 are formed in order over a side wall of the second through hole HL2, and the second conductor portion 292 has a hollow structure filled with a resin material 282. The first conductor portion 291 and the second conductor portion 292 are also generically referred to as a conductor portion 290.

As described above, the first magnetic material portion 391 and the second magnetic material portion 392 (also generically referred to as a magnetic material portion 390) are formed within the resin substrate 190. A step of forming the magnetic material portion 390 is thus required to be performed at or below a heat resistant temperature of the resin substrate 190. With this constraint, the magnetic material portion 390 is not made of a ceramic sintered body, but is made of a resin in which magnetic particles are dispersed. In this case, a gap between the magnetic particles in the magnetic material portion 390 is filled with a resin, and it is normally difficult to increase a filling factor thereof to 70% or more. As a result, relative permeability of the first magnetic material portion 391 and the second magnetic material portion 392 is more difficult to be increased compared with relative permeability of the first magnetic material portion 301 and the second magnetic material portion 302 (FIG. 5), and is approximately 6, for example.

A design example of the core substrate 690 will be described below. The resin substrate 190 has a square shape with sides of 50 mm in the in-plane direction, and has a dimension of 1000 μm in the thickness direction. The plurality of through holes (the first through hole HL1, the second through hole HL2, and the like) are arranged at a pitch of 500 μm. The magnetic material portion 390 has an outer diameter of 400 μm and an inner diameter of 200 μm. The conductor portion 290 has an outer diameter of 200 μm. The conductor portion 290 is formed by Cu plating. The magnetic material portion 390 is made of the resin in which the magnetic particles are dispersed, and assume that relative permeability thereof is estimated to be 6. A single inductor (e.g., the inductor L1) in this case has an inductance of approximately 1 nH at 140 MHz according to estimates of the inventors. The value is half the value estimated to be approximately 2 nH in the present embodiment.

According to the present embodiment, the magnetic material portion 300 (FIG. 5) is not made of the resin in which the magnetic particles are dispersed as with the magnetic material portion 390 (FIG. 7), but is made of the ceramic sintered body. Permeability of the magnetic material portion 300 can thereby sufficiently be increased by densely sintering the ceramics. The inductor having a large inductance per unit area can thus be built in the core substrate 601. Furthermore, the ceramic substrate 100 and the magnetic material portion 300 are inorganically bonded together. This eliminates the need for use of a resin to bond the ceramic substrate 100 and the magnetic material portion 300 together. Reduction in heat resistance of the core substrate 601 due to the use of the resin is thereby avoided. Furthermore, the conductor portion 200 is made of the sintered material including the sintered metal. Variation of electrical characteristics, in particular, conductivity of the conductor portion 200 can thus be suppressed compared with a case where the conductor portion 200 is a plating film. Electrical characteristics of the core substrate can thus be stabilized. In view of the foregoing, the core substrate 601 can include a built-in inductor having a large inductance per unit area, and have a high heat resistance and stable electrical characteristics.

The conductor portion 200 is the non-hollow body. Electrical resistance of the conductor portion 200 can thereby be reduced.

The conductor portion 200 and the magnetic material portion 300 are bonded together without an organic material interposed therebetween. In other words, the conductor portion 200 and the magnetic material portion 300 are inorganically bonded together. Specifically, the conductor portion 200 and the magnetic material portion 300 are sintered together. Heat resistance of the core substrate 601 can thereby be increased compared with a case where the conductor portion 200 and the magnetic material portion 300 are bonded together via an organic material.

The ceramic substrate 100 (FIG. 5) has a higher stiffness than the resin substrate 190 (FIG. 7). The ceramic substrate 100 is thus less likely to warp even after addition of another member to the ceramic substrate 100. The core substrate 601 having smaller warpage can thus be obtained. By suppressing warpage, the formation yield of the wiring layer 791 and the wiring layer 792 (FIG. 1), in particular, the yield of the wiring layer 791 including the wiring structure having a high density is improved first. Second, the mounting yield of the semiconductor element 811 (FIG. 1) is improved.

When the magnetic material portion 300 has the circular inner edge and the circular outer edge in cross section (FIG. 6) perpendicular to the thickness direction, the magnetic material portion 300 can be disposed isotropically with respect to the conductor portion 200 in the cross section.

When the magnetic material portion 300 has a compactness of 70% or more, permeability of the magnetic material portion 300 is likely to be sufficiently increased.

When the ceramic substrate 100 has a coefficient of thermal expansion of 4 ppm/° C. or more and 16 ppm/° C. or less, the coefficient of thermal expansion of the ceramic substrate 100 is between the coefficient of thermal expansion of the semiconductor element 811 (FIG. 1) to be mounted to the interposer 700 including the core substrate 601 and the coefficient of thermal expansion of the typical motherboard 812 (FIG. 1) to which the interposer 700 is to be mounted. Warpage in the electronic equipment 901 (FIG. 1) or the electronic equipment 902 (FIG. 2) due to thermal expansion and contraction can thereby be suppressed.

When the magnetic material portion 300 is made of an insulator, diffusion of a current from the conductor portion 200 to the magnetic material portion 300 can be avoided even when the magnetic material portion 300 is in direct contact with the conductor portion 200 as illustrated in FIGS. 5 and 6.

When the magnetic material portion 300 is in direct contact with the conductor portion 200, a region in which the magnetic material portion 300 is disposed is likely to be sufficiently secured.

The core substrate 601 includes the inductor L1 including the first conductor portion 201 and the first magnetic material portion 301 and the inductor L2 including the second conductor portion 202 and the second magnetic material portion 302. The plurality of inductors can thereby be built in the core substrate 601.

The interconnecting portion 450 electrically connects the one end (a lower end in FIG. 5) of the first conductor portion 201 and the one end (a lower end in FIG. 5) of the second conductor portion 202 on the first surface SF1 of the ceramic substrate 100. The inductor L1 including the first conductor portion 201 and the first magnetic material portion 301 and the inductor L2 including the second conductor portion 202 and the second magnetic material portion 302 can thereby electrically be connected to each other.

When the other end (an upper end in FIG. 5) of the first conductor portion 201 and the other end (an upper end in FIG. 5) of the second conductor portion 202 are electrically separated from each other as illustrated in FIG. 5, the inductor L1 including the first conductor portion 201 and the first magnetic material portion 301 and the inductor L2 including the second conductor portion 202 and the second magnetic material portion 302 are connected not in parallel but in series. The combined inductance can thus be increased.

### Embodiment 2

FIG. 8 is a partial cross-sectional view schematically showing a configuration of a core substrate 602 in Embodiment 2. The core substrate 602 does not include the interconnecting portion 450 (FIG. 5: Embodiment 1). The core substrate 602 also does not include the electrode portion 401 and the electrode portion 402 (FIG. 5: Embodiment 1). The other configuration is substantially the same as the above-mentioned configuration in Embodiment 1, so that the same or corresponding components bear the same reference signs, and description thereof is not repeated. According to the core substrate 602 in the present embodiment, the configuration can be simplified compared with that of the core substrate 601 (FIG. 5: Embodiment 1) while the inductors L1 and L2 are built as in the core substrate 601.

### Embodiment 3

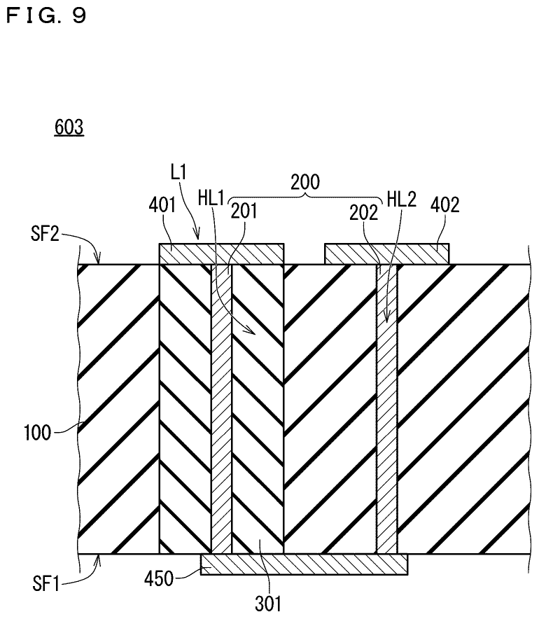

FIG. 9 is a partial cross-sectional view schematically showing a configuration of a core substrate 603 in Embodiment 3. The core substrate 603 does not include the second magnetic material portion 302 (FIG. 5: Embodiment 1). The other configuration is substantially the same as the above-mentioned configuration in Embodiment 1, so that the same or corresponding components bear the same reference signs, and description thereof is not repeated. Also in the core substrate 603 in the present embodiment, the inductor can be disposed between the electrode portion 401 and the electrode portion 402 as in the core substrate 601 (FIG. 5: Embodiment 1). The inductor includes the inductor L1 as in Embodiment 1, but does not include the inductor L2 (FIG. 5) in contrast to Embodiment 1.

### Embodiment 4

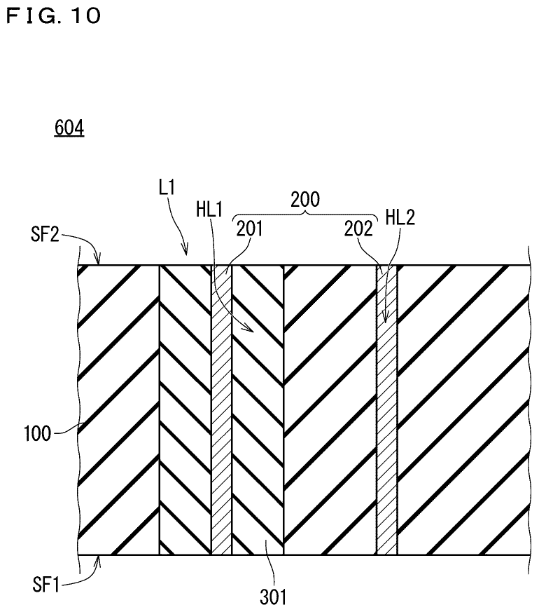

FIG. 10 is a partial cross-sectional view schematically showing a configuration of a core substrate 604 in Embodiment 4. The core substrate 604 does not include the interconnecting portion 450 (FIG. 9: Embodiment 3). The core substrate 604 also does not include the electrode portion 401 and the electrode portion 402 (FIG. 9: Embodiment 3). The other configuration is substantially the same as the above-mentioned configuration in Embodiment 3, so that the same or corresponding components bear the same reference signs, and description thereof is not repeated. According to the core substrate 604 in the present embodiment, the configuration can be simplified compared with that of the core substrate 603 (FIG. 9: Embodiment 3) while the inductor L1 is built as in the core substrate 603.

### Embodiment 5

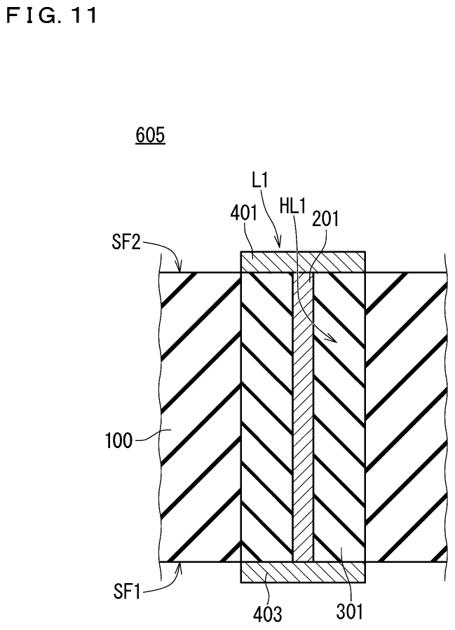

FIG. 11 is a partial cross-sectional view schematically showing a configuration of a core substrate 605 in Embodiment 5. The core substrate 605 does not include the interconnecting portion 450 and the second conductor portion 202 (FIG. 9: Embodiment 3). The core substrate 605 includes an electrode portion 403 (a terminal) connected to the one end of the first conductor portion 201 on the first surface in place of the electrode portion 402 on the second surface SF2. The electrode portion 403 faces each of the first conductor portion 201 and the first magnetic material portion 301 in the thickness direction (vertical direction in FIG. 5). The electrode portion 403 is preferably a terminal made of a sintered material including sintered metal. The other configuration is substantially the same as the above-mentioned configuration in Embodiment 3, so that the same or corresponding components bear the same reference signs, and description thereof is not repeated. According to the core substrate 605 in the present embodiment, the configuration can be simplified compared with that of the core substrate 603 (FIG. 9: Embodiment 3) while the inductor L1 is built as in the core substrate 603.

### Embodiment 6

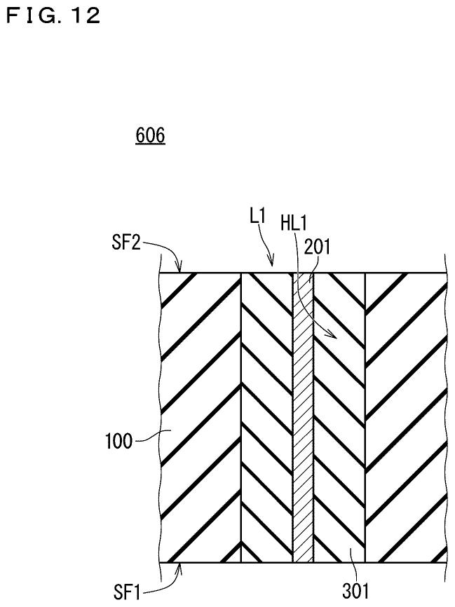

FIG. 12 is a partial cross-sectional view schematically showing a configuration of a core substrate 606 in Embodiment 6. The core substrate 606 does not include the electrode portion 401 and the electrode portion 403 (FIG. 11: Embodiment 5). The other configuration is substantially the same as the above-mentioned configuration in Embodiment 5, so that the same or corresponding components bear the same reference signs, and description thereof is not repeated. According to the core substrate 606 in the present embodiment, the configuration can be simplified compared with that of the core substrate 605 (FIG. 11: Embodiment 5) while the inductor L1 is built as in the core substrate 605.

### Embodiment 7

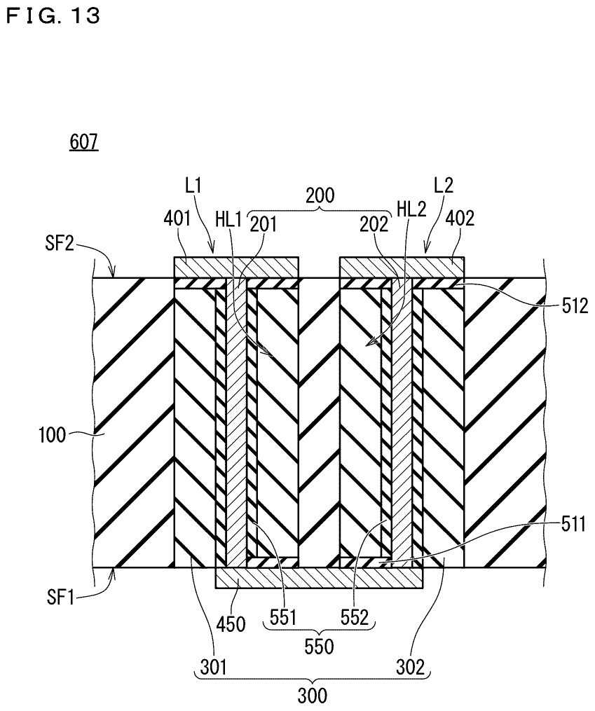

FIG. 13 is a partial cross-sectional view schematically showing a configuration of a core substrate 607 in Embodiment 7.

The core substrate 607 includes a plurality of insulator ceramic films 550 including a first insulator ceramic film 551 and a second insulator ceramic film 552. The first insulator ceramic film 551 separates the first magnetic material portion 301 from the first conductor portion 201. The second insulator ceramic film 552 separates the second magnetic material portion 302 from the second conductor portion 202.

The core substrate 607 includes an insulator layer 511 at least partially covering each of the first magnetic material portion 301 and the second magnetic material portion 302 along a plane including the first surface SF1 of the ceramic substrate 100. The insulator layer 511 separates the interconnecting portion 450 and each of the first magnetic material portion 301 and the second magnetic material portion 302. The insulator layer 511 may partially cover each of the first magnetic material portion 301 and the second magnetic material portion 302 as illustrated.

The core substrate 607 includes an insulator layer 512 at least partially covering each of the first magnetic material portion 301 and the second magnetic material portion 302 along a plane including the second surface SF2 of the ceramic substrate 100. The insulator layer 512 separates the first magnetic material portion 301 and the electrode portion 401, and separates the second magnetic material portion 302 and the electrode portion 402. The insulator layer 512 may entirely cover each of the first magnetic material portion 301 and the second magnetic material portion 302 as illustrated.

The insulator layer 511 and the insulator layer 512 may be made of a non-magnetic material. The insulator layer 511 and the insulator layer 512 are made of an inorganic material, an organic material, or a mixture thereof. The inorganic material may be the same as or different from a material for the ceramic substrate 100. The insulator ceramic films 550 may be made of a non-magnetic material. A material for the insulator ceramic films 550 may be the same as or different from the material for the ceramic substrate 100. A material for the insulator layer 511, a material for the insulator layer 512, and the material for the insulator ceramic films 550 may be different from one another, but are preferably a common material. The common material may be the same as or different from the material for the ceramic substrate 100.

The other configuration is substantially the same as the above-mentioned configuration in Embodiment 1, so that the same or corresponding components bear the same reference signs, and description thereof is not repeated.

According to the present embodiment, the insulator ceramic films 550 separate the magnetic material portion 300 from the conductor portion 200. An adverse effect due to direct contact between the conductor portion 200 and the magnetic material portion 300 can thereby be avoided. In particular, when the magnetic material portion 300 has non-negligible conductivity (in particular, when the magnetic material portion 300 is a conductor), diffusion of a current from the conductor portion 200 to the magnetic material portion 300 can be prevented.

### Embodiment 8

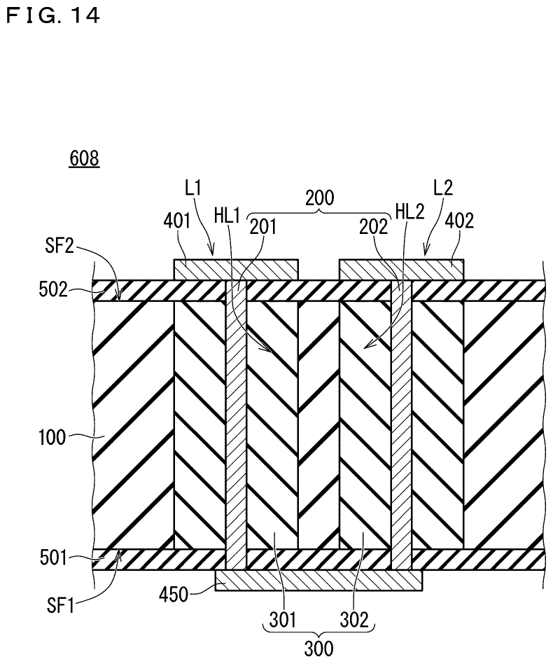

FIG. 14 is a partial cross-sectional view schematically showing a configuration of a core substrate 608 in Embodiment 8.

The core substrate 608 includes an insulator layer 501 at least partially covering each of the first magnetic material portion 301 and the second magnetic material portion 302 along a plane including the first surface SF1 of the ceramic substrate 100. The insulator layer 501 separates the interconnecting portion 450 and each of the first magnetic material portion 301 and the second magnetic material portion 302. The insulator layer 501 may entirely cover the first magnetic material portion 301 and the second magnetic material portion 302 along the plane including the first surface SF1 as illustrated.

The core substrate 608 includes an insulator layer 502 at least partially covering each of the first magnetic material portion 301 and the second magnetic material portion 302 along a plane including the second surface SF2 of the ceramic substrate 100. The insulator layer 502 separates the first magnetic material portion 301 and the electrode portion 401, and separates the second magnetic material portion 302 and the electrode portion 402. The insulator layer 502 may entirely cover the first magnetic material portion 301 and the second magnetic material portion 302 along the plane including the second surface SF2 as illustrated.

The insulator layer 501 and the insulator layer 502 may be made of a non-magnetic material. The insulator layer 501 and the insulator layer 502 are made of an inorganic material, an organic material, or a mixture thereof. The inorganic material may be the same as or different from the material for the ceramic substrate 100. A material for the insulator layer 501 and a material for the insulator layer 502 may be different from each other, but are preferably a common material. The common material may be the same as or different from the material for the ceramic substrate 100.

The other configuration is substantially the same as the above-mentioned configuration in Embodiment 1, so that the same or corresponding components bear the same reference signs, and description thereof is not repeated.

According to the present embodiment, the insulator layer 501 at least partially covers the magnetic material portion 300 along the plane including the first surface SF1 of the ceramic substrate 100. An effect between the magnetic material portion 300 and a configuration over the first surface SF1 can thereby be suppressed. Furthermore, the insulator layer 502 at least partially covers the magnetic material portion 300 along the plane including the second surface SF2 of the ceramic substrate 100. An effect between the magnetic material portion 300 and a configuration over the second surface SF2 can thereby be suppressed.

### Embodiment 9

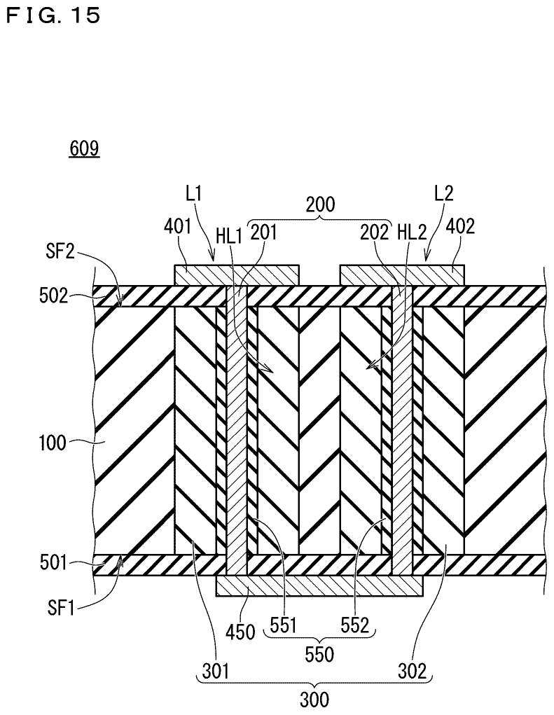

FIG. 15 is a partial cross-sectional view schematically showing a configuration of a core substrate 609 in Embodiment 9. The core substrate 609 includes the insulator ceramic films 550 (FIG. 13: Embodiment 7) in addition to the configuration of the core substrate 608 (FIG. 14: Embodiment 8). The materials for the insulator layer 501 and the insulator layer 502 may be the same as or different from the material for the ceramic substrate 100. In each of the former case and the latter case, the material for the insulator ceramic films 550 may be the same as or different from the material for the ceramic substrate 100.

The other configuration is substantially the same as the above-mentioned configuration in Embodiment 7 or 8, so that the same or corresponding components bear the same reference signs, and description thereof is not repeated.

### Embodiment 10

In each of the core substrate 608 (FIG. 14: Embodiment 8) and the core substrate 609 (FIG. 15: Embodiment 9) described above, a boundary surface between the conductor portion 200 and the interconnecting portion 450 and a boundary surface between the insulator layer 501 and the interconnecting portion 450 are substantially coplanar with each other. Also in each of the core substrate 608 and the core substrate 609, a boundary surface between the electrode portion 401 and the first conductor portion 201 and a boundary surface between the electrode portion 401 and the insulator layer 502 are substantially coplanar with each other, and a boundary surface between the electrode portion 402 and the second conductor portion 202 and a boundary surface between the electrode portion 402 and the insulator layer 502 are substantially coplanar with each other. Arrangement of the boundary surfaces, however, is not limited to this arrangement. For example, Embodiment 9 described above and Embodiment 10 described below differ in arrangement of the boundary surfaces.

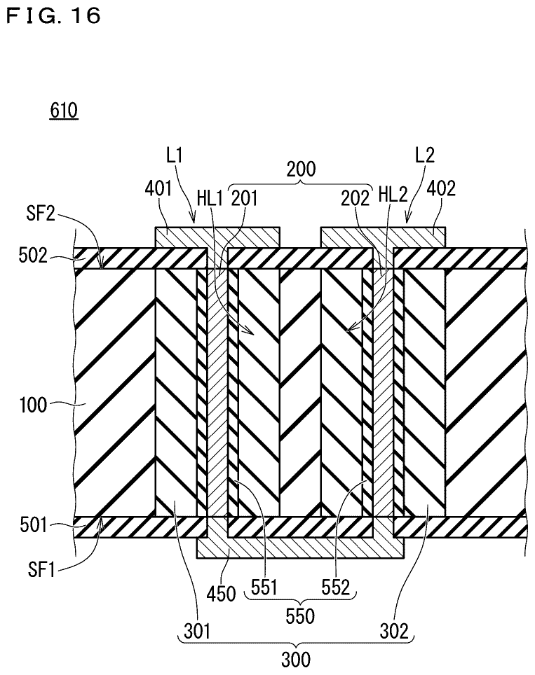

FIG. 16 is a partial cross-sectional view schematically showing a configuration of a core substrate 610 in Embodiment 10. In the core substrate 610, the boundary surface between the conductor 200 and the interconnecting portion 450 is substantially coincident with the first surface SF1 of the ceramic substrate 100. The boundary surface between the electrode portion 401 and the first conductor portion 201 and the boundary surface between the electrode portion 402 and the second conductor portion 202 are each substantially coincident with the second surface SF2 of the ceramic substrate 100.

The above-mentioned boundary surface between the conductor portion 200 and a wiring portion connected thereto (the interconnecting portion 450, the electrode portion 401, the electrode portion 402, the electrode portion 403, and the like in the present embodiment and the other embodiments) may be a microscopically observable boundary surface, but may alternatively be an imaginary boundary surface. The imaginary boundary surface may be assumed irrespective of the microscopically observable boundary surface.

### Embodiment 11

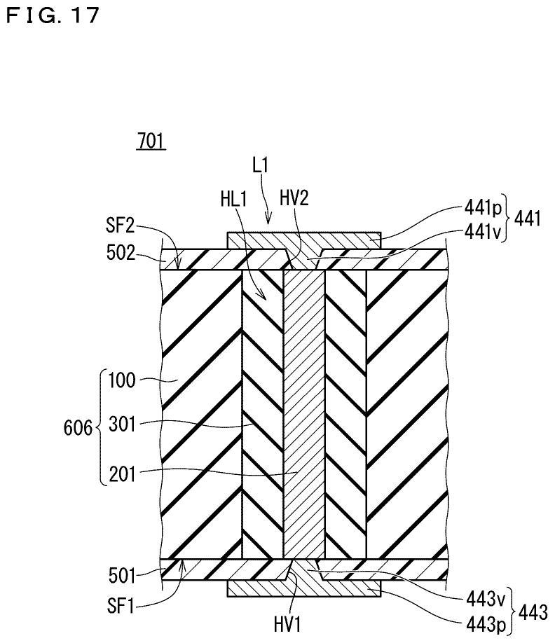

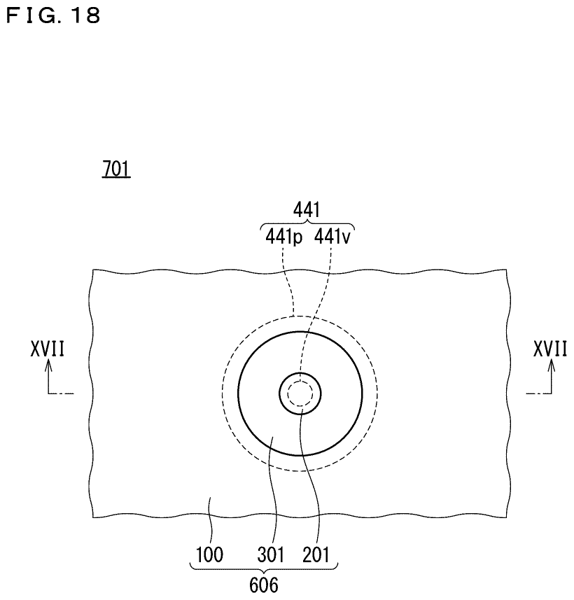

FIG. 17 is a diagram schematically showing a configuration of an interposer 701 in Embodiment 11, and is a partial cross-sectional view taken along the line XVII-XVII of FIG. 18. FIG. 18 is a partial plan view schematically showing a configuration of the second surface SF2 of the interposer 701 in FIG. 17. The interposer 701 is one example of the interposer 700 (FIG. 1 or 2). Specifically, the interposer 701 includes the core substrate 606 (FIG. 12: Embodiment 6), a wiring portion 441 and the insulator layer 502 as the wiring layer 791 (FIG. 1 or 2), and a wiring portion 443 and the insulator layer 501 as the wiring layer 792 (FIG. 1 or 2). In FIG. 18, the configuration of the core substrate 606 is indicated by solid lines, and another configuration added to the core substrate 606 is indicated by dashed lines for clarity of illustration.

The wiring portion 441 includes a wiring pattern 441p and a connecting via 441v. The connecting via 441v has a bottom surface connected to the first conductor portion 201 of the core substrate 606. The bottom surface of the connecting via 441v is separated from the first magnetic material portion 301 and the ceramic substrate 100. While a pattern layout of the wiring pattern 441p is circular in FIG. 18, a shape of the pattern layout is not limited to this shape, and the pattern layout may be designed as appropriate in response to a circuit configuration required for the interposer 701.

Similarly, the wiring portion 443 includes a wiring pattern 443p and a connecting via 443v. The connecting via 443v has a bottom surface connected to the first conductor portion 201 of the core substrate 606. The bottom surface of the connecting via 443v is separated from the first magnetic material portion 301 and the ceramic substrate 100. A pattern layout of the wiring pattern 443p may be designed as appropriate in response to the circuit configuration required for the interposer 701.

The insulator layer 502 has a via hole HV2 in which the connecting via 441v is disposed. The via hole HV2 is preferably tapered toward the first conductor portion 201 as illustrated in FIG. 17, but a shape of the via hole HV2 is no limited to this shape, and the via hole HV2 may be straight. The insulator layer 502 separates the wiring portion 441 and each of the first magnetic material portion 301 and the ceramic substrate 100 of the core substrate 606. The insulator layer 502 preferably contains organic matter, may be an organic insulator layer, and may be an epoxy-based resin layer, for example.

Similarly, the insulator layer 501 has a via hole HV1 in which the connecting via 443v is disposed. The via hole HV1 is preferably tapered toward the first conductor portion 201 as illustrated in FIG. 17, but a shape of the via hole HV1 is no limited to this shape, and the via hole HV1 may be straight. The insulator layer 501 separates the wiring portion 443 and each of the first magnetic material portion 301 and the ceramic substrate 100 of the core substrate 606. The insulator layer 501 preferably contains organic matter, may be an organic insulator layer, and may be an epoxy-based resin layer, for example.

The wiring portion 441 may be a plating layer. In this case, the wiring portion 441 and the insulator layer 502 may be formed by a semi-additive method, and may generally be formed as described below, for example. An organic insulating film as the insulator layer 502 not having the via hole HV2 yet is attached to the second surface SF2 of the core substrate 606. Next, the via hole HV2 is formed by laser processing. Next, a seed layer is formed on a surface of the insulator layer 502 including an inner surface of the via hole HV2 by electroless copper plating. Next, a plating resist exposing a region in which the wiring pattern 441p of the wiring portion 441 is to be formed is formed over the insulator layer 502. Next, electrolytic copper plating is performed using the seed layer and the plating resist described above. Next, the plating resist is stripped. The wiring portion 441 is formed as described above. The wiring portion 443 and the insulator layer 501 may similarly be formed.

According to the present embodiment, the bottom surface of the connecting via 441v is separated from the magnetic material portion 301 and the ceramic substrate 100. Specifically, the insulator layer 502 separates the wiring portion 441 and each of the first magnetic material portion 301 and the ceramic substrate 100 of the core substrate 606. Inclusion of components of the first magnetic material portion 301 and the ceramic substrate 100 into the wiring portion 441 can thereby be avoided. Specifically, elution of components of the first magnetic material portion 301 and the ceramic substrate 100 into a plating solution to form the plating layer as the wiring portion 441 can be avoided. Variation of electrical characteristics (in particular, conductivity) of the wiring portion 441 can thereby be suppressed. The same applies to the wiring portion 443.

When the via hole HV2 of the insulator layer 502 is tapered toward the first conductor portion 201, the size of the via hole HV2 can be larger at a position away from the first conductor portion 201 while a configuration as described above is secured. Electrical resistance of the connecting via 441v disposed therein can thereby be reduced. The same applies to the via hole HV1 of the insulator layer 501.

When the insulator layer 502 contains organic matter (in particular, when the insulator layer 502 is an organic insulator layer), inclusion of components of the first magnetic material portion 301 and the ceramic substrate 100 into the wiring portion 441 is more likely to be avoided. Specifically, elution of components of the first magnetic material portion 301 and the ceramic substrate 100 into the plating solution to form the plating layer as the wiring portion 441 is more likely to be avoided.

While the core substrate 606 in Embodiment 6 is used as the core substrate of the interposer in the present embodiment, the core substrate in another embodiment may be used.

### Embodiment 12

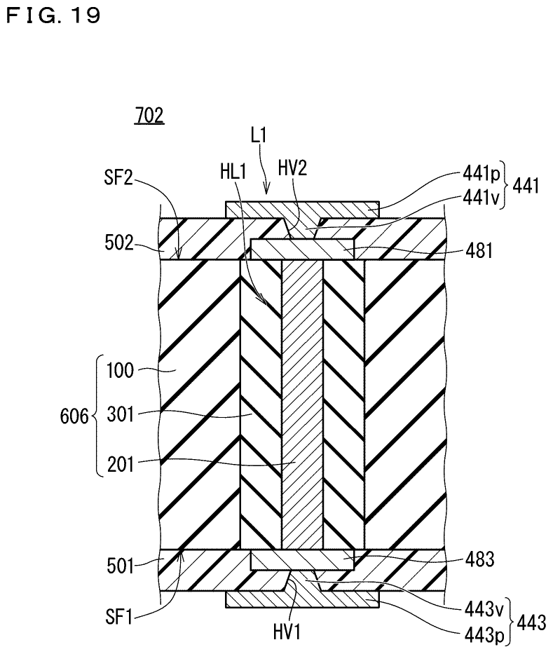

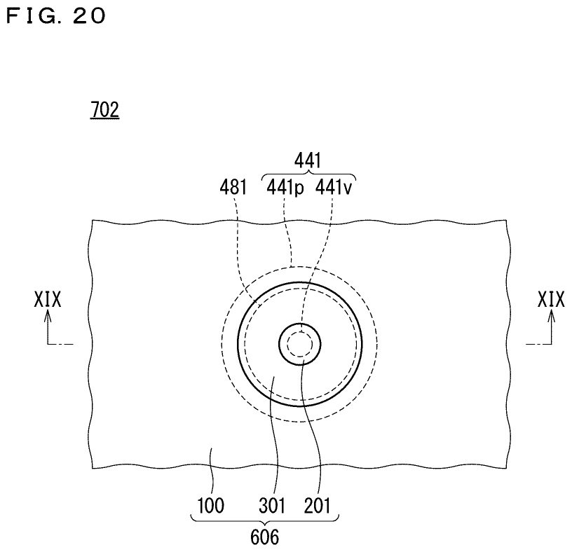

FIG. 19 is a diagram schematically showing a configuration of an interposer 702 in Embodiment 12, and is a partial cross-sectional view taken along the line XIX-XIX of FIG. 20. FIG. 20 is a partial plan view schematically showing a configuration of the second surface SF2 of the interposer 702 in FIG. 19. The interposer 702 is one example of the interposer 700 (FIG. 1 or 2). Specifically, the interposer 702 includes the core substrate 606 (FIG. 12: Embodiment 6), the wiring portion 441, the insulator layer 502, and an electrode pad 481 (a terminal) as the wiring layer 791 (FIG. 1 or 2), and the wiring portion 443, the insulator layer 501, and an electrode pad 483 (a terminal) as the wiring layer 792 (FIG. 1 or 2). In FIG. 20, the configuration of the core substrate 606 is indicated by solid lines, and another configuration added to the core substrate 606 is indicated by dashed lines for clarity of illustration.

The electrode pad 481 is connected to the first conductor portion 201 of the core substrate 606. The electrode pad 481 faces each of the first conductor portion 201 and the first magnetic material portion 301 in the thickness direction (vertical direction in FIG. 19). The electrode pad 481 and each of the first conductor portion 201 and the first magnetic material portion 301 are inorganically bonded together. The bottom surface of the connecting via 441v of the wiring portion 441 is connected to the electrode pad 481 in the present embodiment in contrast to Embodiment 11 described above. The bottom surface of the connecting via 441v is separated from the first magnetic material portion 301 and the ceramic substrate 100. The electrode pad 481 covers the first conductor portion 201. The electrode pad 481 may have a portion covering the first magnetic material portion 301. Specifically, the electrode pad 481 may partially cover the first magnetic material portion 301 along the second surface SF2 as illustrated in FIG. 19. In this case, an edge of the electrode pad 481 is disposed on the first magnetic material portion 301 as illustrated in FIGS. 19 and 20. As a modification, the electrode pad 481 may exactly cover the first magnetic material portion 301 along the second surface SF2, and, in this case, the edge of the electrode pad 481 is disposed on a boundary between the first magnetic material portion 301 and the ceramic substrate 100. As another modification, the electrode pad 481 may cover the first magnetic material portion 301 while having a margin, and, in this case, the edge of the electrode pad 481 is disposed on the ceramic substrate 100 away from the above-mentioned boundary. The electrode pad 481 is made of a sintered material including sintered metal. The electrode pad 481 made of the sintered material can be formed by printing and sintering of a paste layer. The electrode pad 481 may contain silver, copper, a silver-palladium alloy, or a silver-copper alloy as a main component, and may be a sintered silver layer, a sintered copper layer, a sintered silver-palladium alloy layer, or a sintered silver-copper alloy layer, for example.

Similarly, the electrode pad 483 is connected to the first conductor portion 201 of the core substrate 606. The electrode pad 483 faces each of the first conductor portion 201 and the first magnetic material portion 301 in the thickness direction (vertical direction in FIG. 19). The electrode pad 483 and each of the first conductor portion 201 and the first magnetic material portion 301 are inorganically bonded together. The bottom surface of the connecting via 443v of the wiring portion 443 is connected to the electrode pad 483 in the present embodiment in contrast to Embodiment 11 described above. The bottom surface of the connecting via 443v is separated from the first magnetic material portion 301 and the ceramic substrate 100. The electrode pad 483 covers the first conductor portion 201. The electrode pad 483 may have a portion covering the first magnetic material portion 301. Specifically, the electrode pad 483 may partially cover the first magnetic material portion 301 along the first surface SF1 as illustrated in FIG. 19. In this case, an edge of the electrode pad 483 is disposed on the first magnetic material portion 301 as illustrated in FIG. 19. As a modification, the electrode pad 483 may exactly cover the first magnetic material portion 301 along the first surface SF1, and, in this case, the edge of the electrode pad 483 is disposed on a boundary between the first magnetic material portion 301 and the ceramic substrate 100. As another modification, the electrode pad 483 may cover the first magnetic material portion 301 while having a margin, and, in this case, the edge of the electrode pad 483 is disposed on the ceramic substrate 100 away from the above-mentioned boundary. The electrode pad 483 is made of a sintered material including sintered metal. The electrode pad 483 made of the sintered material can be formed by printing and sintering of a paste layer. The electrode pad 483 may contain silver, copper, a silver-palladium alloy, or a silver-copper alloy as a main component, and may be a sintered silver layer, a sintered copper layer, a silver-palladium alloy layer, or a sintered silver-copper alloy layer, for example.

The other configuration is substantially the same as the above-mentioned configuration in Embodiment 11, so that the same or corresponding components bear the same reference signs, and description thereof is not repeated.

According to the present embodiment, the bottom surface of the connecting via 441v is separated from the first magnetic material portion 301 and the ceramic substrate 100. Specifically, the insulator layer 502 and the electrode pad 481 separate the wiring portion 441 and each of the first magnetic material portion 301 and the ceramic substrate 100 of the core substrate 606. Inclusion of components of the first magnetic material portion 301 and the ceramic substrate 100 into the wiring portion 441 can thereby be avoided. Specifically, elution of components of the first magnetic material portion 301 and the ceramic substrate 100 into the plating solution to form the plating layer as the wiring portion 441 can be avoided. Variation of the electrical characteristics, in particular, conductivity of the wiring portion 441 can thereby be suppressed. The same applies to the wiring portion 443.

When the electrode pad 481 has the portion covering the first magnetic material portion 301, inclusion of components of the first magnetic material portion 301 can more reliably be avoided. The same applies to the electrode pad 483.

When the electrode pad 481 contains silver, copper, or the silver-copper alloy as a main component, inclusion of components of the electrode pad 481 into the wiring portion 441 is likely to be avoided. Specifically, elution of components of the electrode pad 481 into the plating solution to form the plating layer as the wiring portion 441 is likely to be avoided. Variation of the electrical characteristics (in particular, conductivity) of the wiring portion 441 can thereby more reliably be suppressed. The effect can more reliably be obtained when the electrode pad 481 is substantially made of silver, a silver-palladium alloy, or copper. The effect can also more reliably be obtained when the electrode pad 481 is the sintered silver layer, the sintered silver-palladium alloy layer, or the sintered copper layer. The electrode pad 481 is thus preferably the sintered silver layer, the sintered silver-palladium alloy layer, or the sintered copper layer. The same applies to the electrode pad 483.

While the core substrate 606 in Embodiment 6 is used as the core substrate of the interposer in the present embodiment, the core substrate in another embodiment may be used.

### Embodiment 13

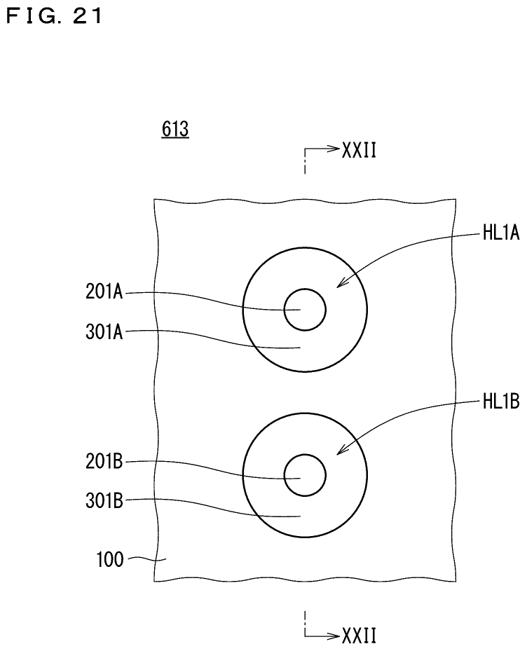

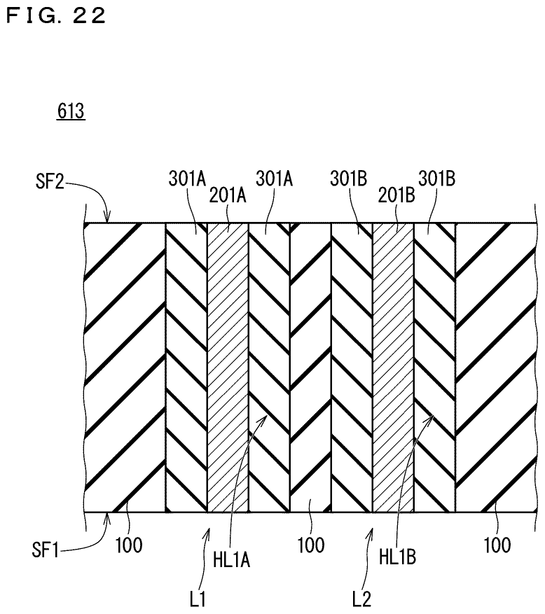

FIG. 21 is a partial plan view schematically showing a configuration of a core substrate 613 in Embodiment 13. FIG. 22 is a partial cross-sectional view taken along the line XXII-XXII of FIG. 21. The core substrate 613 includes the two inductors L1 and L2 (FIG. 22). The inductor L1 includes a conductor portion 201A and a magnetic material portion 301A provided within a through hole HL1A. The inductor L2 includes a conductor portion 201B and a magnetic material portion 301B provided within a through hole HL1B. The magnetic material portion 301A and the magnetic material portion 301B are away from each other. Specifically, the magnetic material portion 301A and the magnetic material portion 301B are separated by the ceramic substrate 100. Each of the inductors L1 and L2 of the core substrate 613 may have a similar configuration to the inductor L1 of the core substrate 606 (FIG. 12: Embodiment 6).

### Embodiment 14

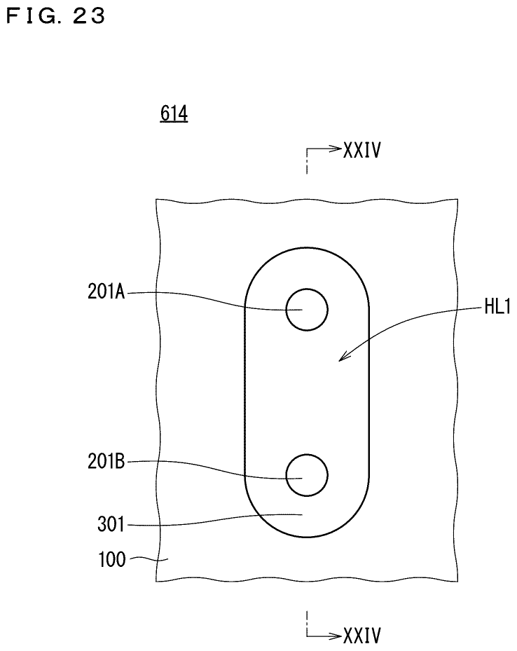

FIG. 23 is a partial plan view schematically showing a configuration of a core substrate 614 in Embodiment 14. FIG. 24 is a partial cross-sectional view taken along the line XXIV-XXIV of FIG. 23. The core substrate 614 includes the two inductors L1 and L2 (FIG. 24). As in Embodiment 13 described above, the inductor L1 and the inductor L2 respectively include the conductor portion 201A and the conductor portion 201B in the present embodiment. On the other hand, in contrast to Embodiment 13 described above, the inductors L1 and L2 share the magnetic material portion 301 provided within the through hole HL1 in Embodiment 14. The conductor portion 201A and the conductor portion 201B are thus separated not by the ceramic substrate 100 but by the magnetic material portion 301.

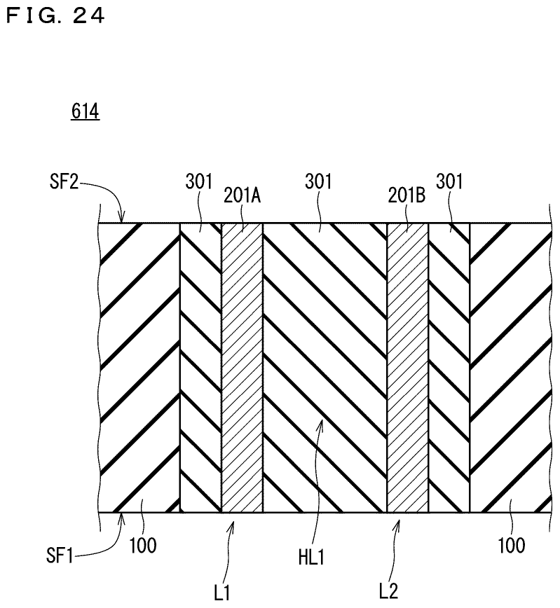

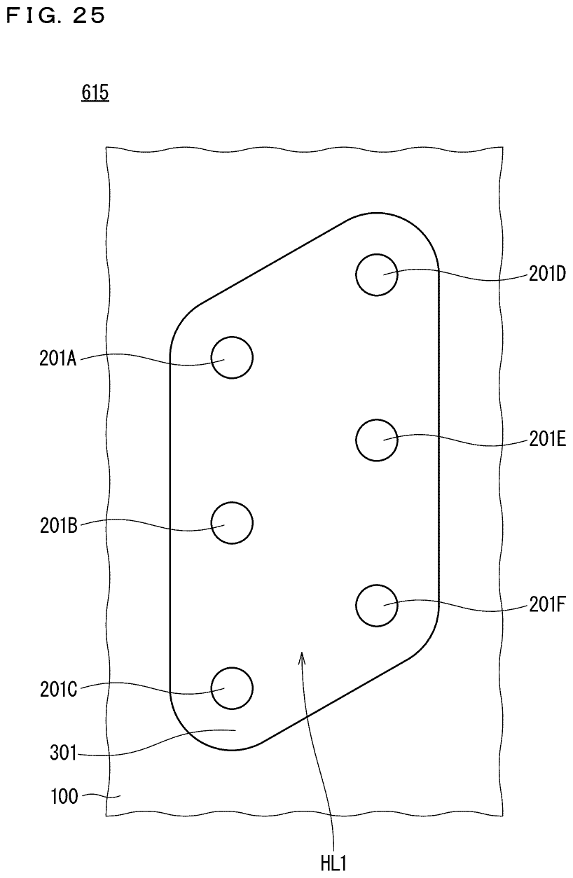

The number of conductor portions provided within the common magnetic material portion 301 is not limited to two as illustrated in FIG. 23. FIG. 25 is a partial plan view illustrating a modification of FIG. 23. In the present modification, six conductor portions 201A to 201F are provided within the common magnetic material portion 301. Arrangement thereof includes arrangement along a first direction (vertical direction in FIG. 25) and arrangement along a second direction (diagonal direction in FIG. 25).

A configuration in which a plurality of conductor portions are arranged within a common magnetic material portion as in the present embodiment may be applied to the core substrate in any of Embodiments 1 to 12 described above.

### Embodiment 15

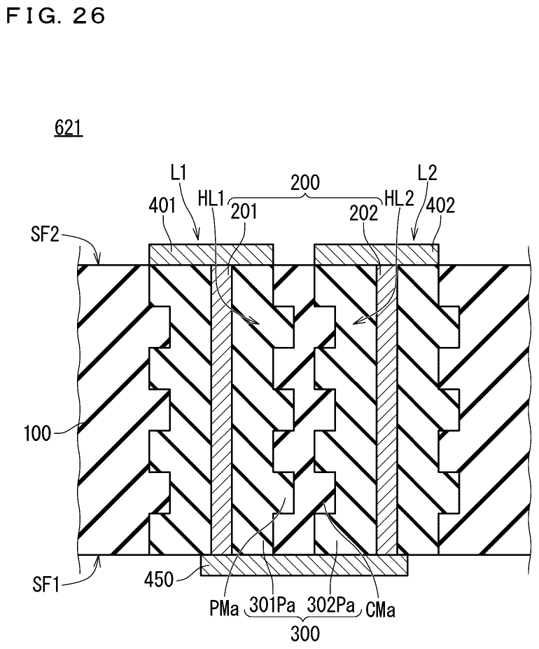

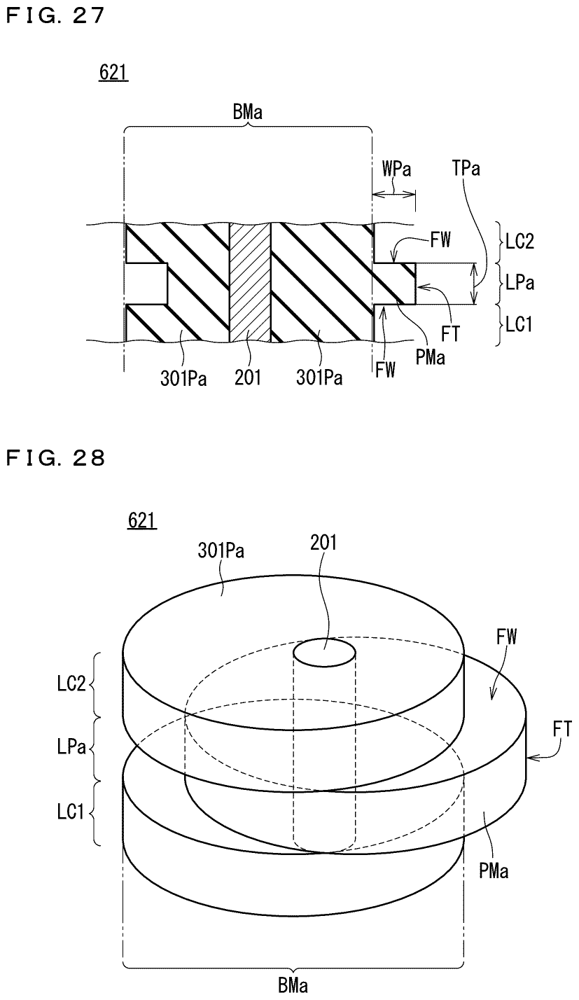

FIG. 26 is a partial cross-sectional view schematically showing a configuration of a core substrate 621 in Embodiment 15. FIG. 27 is a partial enlarged view of FIG. 26. FIG. 28 is a perspective view of FIG. 27. The core substrate 621 (FIG. 26) includes a first magnetic material portion 301Pa and a second magnetic material portion 302Pa in place of the first magnetic material portion 301 and the second magnetic material portion 302 of the core substrate 601 (FIG. 5). The first magnetic material portion 301Pa and the second magnetic material portion 302Pa each has a protruding structure PMa toward the ceramic substrate 100 in cross section including the thickness direction (vertical direction in FIG. 26). Specifically, the first magnetic material portion 301Pa and the second magnetic material portion 302Pa each has the protruding structure PMa into the ceramic substrate 100 in the cross section including the thickness direction (vertical direction in FIG. 26).

The core substrate 621 includes a layer LC1, a layer LC2, and a layer LPa between them in the thickness direction (vertical direction in FIG. 27). The layer LPa is in contact with each of the layer LC1 and the layer LC2. In other words, the layer LC1, the layer LPa, and the layer LC2 are directly stacked in order in the thickness direction. The layer LC1, the layer LPa, and the layer LC2 may correspond to layers stacked when the core substrate 621 is manufactured using laminated ceramic technology.

The first magnetic material portion 301Pa (FIG. 27) falls within a range BMa in an in-plane direction (a direction perpendicular to the thickness direction) in each of the layer LC1 and the layer LC2, and protrudes beyond the range BMa in the layer LPa. A portion of the first magnetic material portion 301Pa protruding beyond the range BMa corresponds to the protruding structure PMa. While an arrangement of the first magnetic material portion 301Pa in the in-plane direction in the layer LC1 and an arrangement of the first magnetic material portion 301Pa in the in-plane direction in the layer LC2 are the same in an example illustrated in FIG. 27, these arrangements may be the same or may be different from each other as long as the first magnetic material portion 301Pa falls within the range BMa. A minimum range within which the first magnetic material portion 301Pa falls in each of the layer LC1 and the layer LC2 is the range BMa.

The protruding structure PMa has a thickness dimension TPa and a width dimension WPa (dimension in a direction perpendicular to the thickness direction). The protruding structure PMa may be substantially rectangular in cross section as illustrated in FIG. 27, and, in this case, the width dimension WPa and the thickness dimension TPa correspond to dimensions of sides of the rectangle. When the protruding structure PMa is formed using the laminated ceramic technology as described above, the rectangular protruding structure PMa can easily be formed, and, in this case, the protruding structure PMa has a pair of surfaces FW substantially parallel to the in-plane direction and an end surface FT substantially parallel to the thickness direction. For example, as illustrated in FIG. 28 (the perspective view), a pattern (shape in the in-plane direction) of the first magnetic material portion 301Pa in each of the layer LC1, the layer LPa, and the layer LC2 may have a circular outer edge, and the protruding structure PMa may be formed by offsetting the pattern in the layer LPa from the pattern in each of the layer LC1 and the layer LC2. As a modification, the protruding structure can be formed by setting a diameter of a circular shape in the layer LPa to a diameter greater than a diameter of a circular shape in each of the layer LC1 and the layer LC2 instead of offsetting the pattern as described above.

The protruding structure PMa (FIG. 27) may be rectangular in cross section as described above, or may have another shape. A maximum width dimension and a maximum thickness dimension of the protruding structure PMa may respectively be considered as the width dimension WPa and the thickness dimension TPa. The width dimension WPa and the thickness dimension TPa are each greater than a particle size of ceramics to form the ceramic substrate 100. When the particle size is 1 μm or more and 10 μm or less, the width dimension WPa is preferably 10 μm or more and 100 μm or less. When the width dimension WPa is 10 μm or more, the protruding structure PMa is likely to sufficiently produce an anchoring effect. When the width dimension WPa is 100 μm or less, cracking of the ceramic substrate 100 due to thermal stress concentration near the protruding structure PMa is likely to be avoided. The thickness dimension TPa is preferably 50 μm or more and 200 μm or less.

The second magnetic material portion 302Pa may have a protruding structure PMa similar to the above-mentioned protruding structure PMa. As illustrated in cross section in FIG. 26, the protruding structure PMa of the first magnetic material portion 301Pa and a recessed structure CMa of the second magnetic material portion 302Pa may face each other in the in-plane direction (a horizontal direction in FIG. 26).

The other configuration of the core substrate 621 is substantially the same as the above-mentioned configuration of the core substrate 601 (FIG. 5: Embodiment 1), so that the same or corresponding components bear the same reference signs, and description thereof is not repeated.

According to the present embodiment, mechanical bonding between the ceramic substrate 100 and each of the first magnetic material portion 301Pa and the second magnetic material portion 302Pa is enhanced by the protruding structure PMa. Deterioration of electrical characteristics of the core substrate 621 with temperature cycling is thereby suppressed. The electrical characteristics of the core substrate 621 can thus further be stabilized.

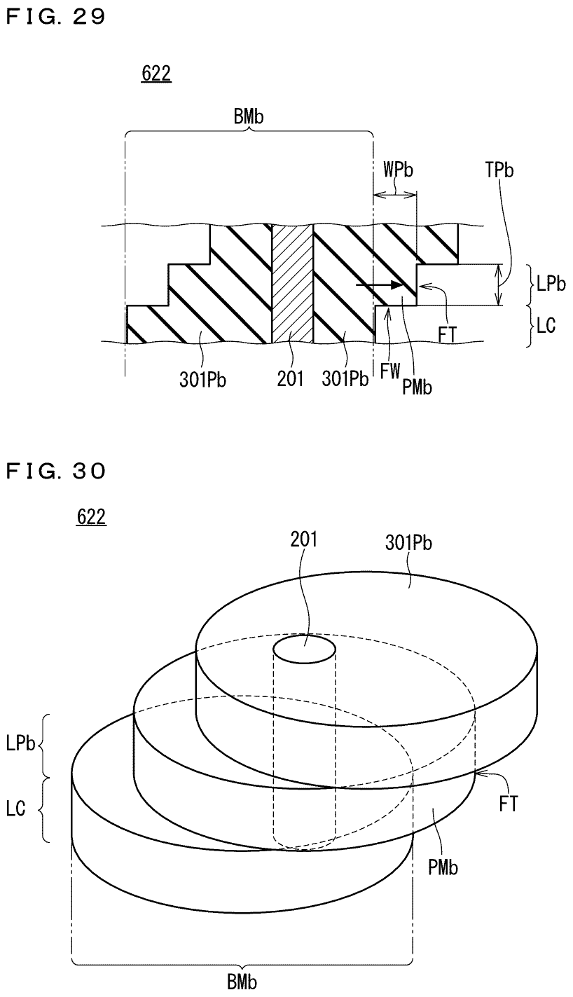

FIG. 29 illustrates a core substrate 622 in a modification of the core substrate 621 (FIG. 27). FIG. 30 is a perspective view of FIG. 29. The core substrate 622 (FIG. 29) includes a first magnetic material portion 301Pb in place of the first magnetic material portion 301Pa of the core substrate 621 (FIG. 27). The first magnetic material portion 301Pb has a step structure PMb facing the ceramic substrate 100.

The core substrate 622 includes a layer LC and a layer LPb directly stacked in the thickness direction (vertical direction in FIG. 29). The layer LC and the layer LPb may correspond to layers stacked when the core substrate 622 is manufactured using the laminated ceramic technology.

The first magnetic material portion 301Pb (FIG. 29) falls within a range BMb in the in-plane direction (direction perpendicular to the thickness direction) in the layer LC, and extends beyond the range BMb in the layer LPb. A portion of the first magnetic material portion 301Pb extending beyond the range BMb corresponds to the step structure PMb. The step structure PMb has a surface FW extending from the range BMb substantially parallel to the in-plane direction and an end surface FT extending from an end of the surface FW substantially parallel to the thickness direction. In cross section (FIG. 29) including the thickness direction, a dimension of the surface FW is defined as a width dimension WPb of the step structure PMb, and a dimension of the end surface FT is defined as a thickness dimension TPb of the step structure PMb. The width dimension WPb and the thickness dimension TPb are each greater than the particle size of ceramics to form the ceramic substrate 100. When the particle size is 1 μm or more and 10 μm or less, the width dimension WPb is preferably 10 μm or more and 100 μm or less, and the thickness dimension TPb is 50 μm or more and 200 μm or less.

For example, as illustrated in FIG. 30 (the perspective view), a pattern (shape in the in-plane direction) of the first magnetic material portion 301Pb in each of the layer LC and the layer LPb may have a circular outer edge, and the step structure PMb may be formed by offsetting the pattern in the layer LPb from the pattern in the layer LC. As a modification, the step structure can be formed by setting a diameter of a circular shape in the layer LPb to a diameter greater than a diameter of a circular shape in the layer LC instead of offsetting the pattern.

The layer LC1 and the layer LPa in Embodiment 15 (FIG. 27) described above can respectively be considered as the layer LC and the layer LPb in the present modification, so that the core substrate 621 having the protruding structure PMa also has the step structure. The protruding structure PMa is likely to produce a greater effect of enhancing mechanical strength than the step structure PMb not forming the protruding structure.

The above-mentioned characteristics of the protruding structure PMa or the step structure PMb regarding the magnetic material portion may be applied to the other embodiments and modifications thereof described herein.

### Embodiment 16

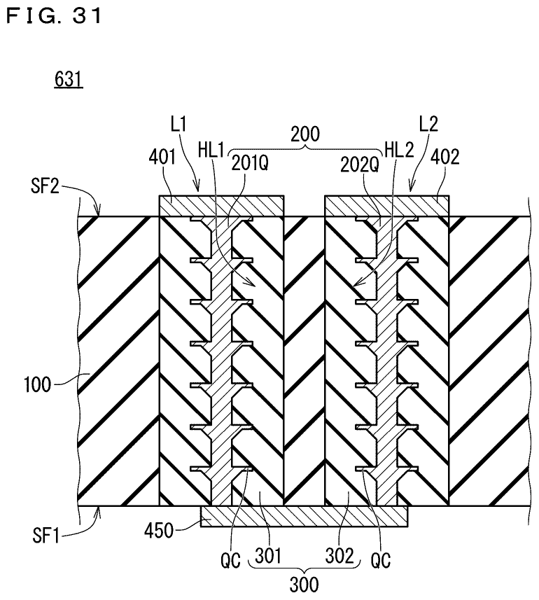

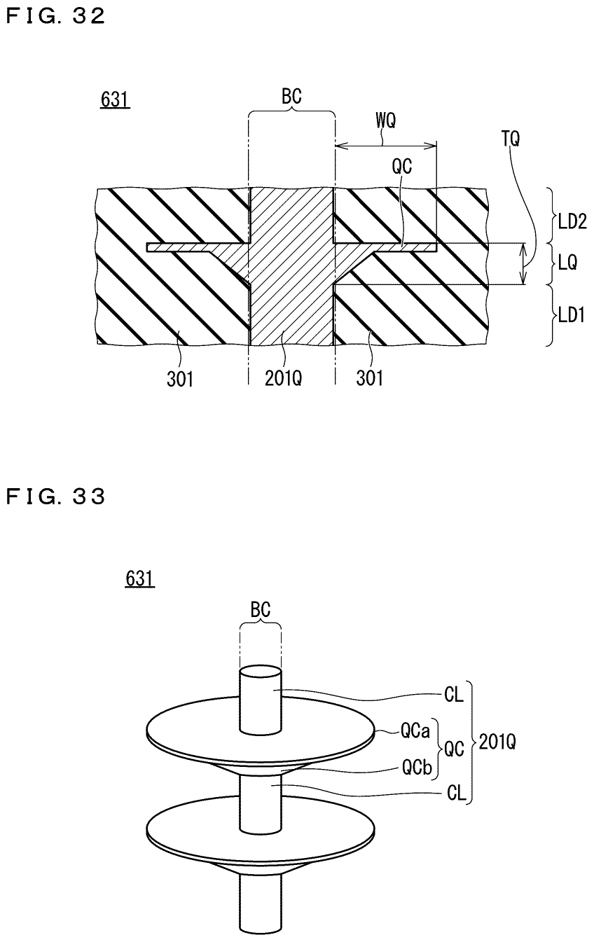

FIG. 31 is a partial cross-sectional view schematically showing a configuration of a core substrate 631 in Embodiment 16. FIG. 32 is a partial enlarged view of FIG. 31. FIG. 33 is a partial perspective view of FIG. 32. The core substrate 631 (FIG. 31) includes a first conductor portion 201Q and a second conductor portion 202Q in place of the first conductor portion 201 and the second conductor portion 202 of the core substrate 601 (FIG. 5). The first conductor portion 201Q and the second conductor portion 202Q respectively have a protruding structure QC toward the first magnetic material portion 301 and a protruding structure QC toward the second magnetic material portion 302 in cross section including the thickness direction (vertical direction in FIG. 32). Specifically, the first conductor portion 201Q and the second conductor portion 202Q respectively have the protruding structure QC into the first magnetic material portion 301 and the protruding structure QC into the second magnetic material portion 302 in the cross section including the thickness direction (vertical direction in FIG. 32).

The core substrate 631 includes a layer LD1, a layer LD2, and a layer LQ between them in the thickness direction (vertical direction in FIG. 32). The layer LQ is in contact with each of the layer LD1 and the layer LD2. In other words, the layer LD1, the layer LQ, and the layer LD2 are directly stacked in order in the thickness direction. The layer LD1, the layer LQ, and the layer LD2 may correspond to layers stacked when the core substrate 631 is manufactured using the laminated ceramic technology.

The first conductor portion 201Q (FIG. 32) falls within a range BC in the in-plane direction (direction perpendicular to the thickness direction) in each of the layer LD1 and the layer LD2, and protrudes beyond the range BC in the layer LQ. A portion of the first conductor portion 201Q protruding beyond the range BC corresponds to the protruding structure QC. While an arrangement of the first conductor portion 201Q in the in-plane direction in the layer LD1 and an arrangement of the first conductor portion 201Q in the in-plane direction in the layer LD2 are the same in an example illustrated in FIG. 32, these arrangements may be the same or may be different from each other as long as the first conductor portion 201Q falls within the range BC. A minimum range within which the first conductor portion 201Q falls in each of the layer LD1 and the layer LD2 is the range BC.

The protruding structure QC has a thickness dimension TQ and a width dimension WQ (dimension in the direction perpendicular to the thickness direction). A maximum width dimension and a maximum thickness dimension of the protruding structure QC may respectively be considered as the width dimension WQ and the thickness dimension TQ. The width dimension WQ and the thickness dimension TQ are each greater than a particle size of the sintered metal to form the magnetic material portion 300. When the particle size is 0.1 μm or more and 3 μm or less, the width dimension WQ is preferably 10 μm or more and 100 μm or less. The thickness dimension TQ is preferably 5 μm or more and 30 μm or less. When these dimensions are not extremely small, the protruding structure QC is likely to sufficiently produce the anchoring effect. When these dimensions are not extremely large, cracking of the magnetic material portion 300 due to thermal stress concentration near the protruding structure QC is likely to be avoided.

As illustrated in FIG. 33 (the perspective view), the protruding structure QC may include a disc portion QCa substantially being disc-shaped and a frustoconical portion QCb substantially being frustoconical. The protruding structure QC may be sandwiched between cylindrical portions CL substantially being cylindrical in the thickness direction. The disc portion QCa is in contact with a bottom surface of the frustoconical portion QCb (a larger one of two circular surfaces of the frustoconical portion). A central axis of the disc portion QCa and a central axis of the frustoconical portion QCb are substantially coincident with each other. The central axis of the frustoconical portion QCb and a central axis of one of the cylindrical portions CL leading to the frustoconical portion QCb are substantially coincident with each other. The bottom surface of the frustoconical portion QCb has a greater diameter than the cylindrical portion CL. The disc portion QCa has a greater diameter than the bottom surface of the frustoconical portion QCb. The protruding structure QC (FIG. 32) including the disc portion QCa and the frustoconical portion QCb can easily be formed when a manufacturing method using the laminated ceramic technology is used. An example of the manufacturing method will be briefly described below.

A single green sheet to be a portion included in the layer LD1 and the layer LQ (FIG. 32) of the ceramic substrate 100 is prepared. A through hole corresponding to the through hole HL1 (FIG. 31) is formed in the green sheet. The through hole of the green sheet is filled with a magnetic material powder paste to be a material for the first magnetic material portion 301. A magnetic material filled portion is formed in the through hole of the green sheet by the filling. A through hole smaller than the through hole of the green sheet is formed in the magnetic material filled portion. The through hole of the magnetic material filled portion has substantially the same diameter as the cylindrical portion CL when firing shrinkage is ignored.

The above-mentioned through hole of the magnetic material filled portion is filled with a conductor powder paste to be a material for the first conductor portion 201Q in a paste printing step. In this printing step, the conductor powder paste is not only loaded into the through hole of the magnetic material filled portion but also applied to a portion around the through hole over an upper surface of the magnetic material filled portion. A degree of application of the conductor powder paste to the portion around the through hole can easily be adjusted by adjusting a size of a printing pattern and the like.

While a portion to be the first magnetic material portion 301 and the first conductor portion 201Q has been described above, the same applies to a portion to be the second magnetic material portion 302 and the second conductor portion 202Q.

The green sheet to be the layer LD1 and the layer LQ is formed in the above-mentioned steps. A green sheet to be a portion including the layer LD2 is formed in steps similar to these steps. A green sheet to be another portion may further be formed. For example, a total of seven green sheets are formed in a configuration illustrated in FIG. 31. These green sheets are stacked to form a stack. The stack is fired to obtain a fired body including the ceramic substrate 100, the first magnetic material portion 301, the second magnetic material portion 302, the first conductor portion 201Q, and the second conductor portion 202Q illustrated in FIG. 31. An electrode paste is printed onto the fired body, and the electrode paste is fired to form terminals (specifically, the electrode portion 401, the electrode portion 402, and the interconnecting portion 450). The core substrate 631 is thereby obtained.

A portion of the conductor powder paste loaded into the through hole of the magnetic material filled portion in the above-mentioned manufacturing method is to be the cylindrical portion CL. A portion of the conductor powder paste applied to the portion around the through hole over the upper surface of the magnetic material filled portion is to be the disc portion QCa. The frustoconical portion QCb is formed near a portion in which the cylindrical portion CL and the disc portion QCa are connected to each other as a result in response to various conditions in the above-mentioned manufacturing method. The diameter of the disc portion QCa can easily be adjusted by adjusting the size of the printing pattern of the conductor powder paste as described above. In other words, the width dimension WQ (FIG. 32) of the protruding structure QC can easily be adjusted.

As illustrated in cross section in FIG. 31, the protruding structure QC of the first conductor portion 201Q and the protruding structure QC of the second conductor portion 202Q may face each other in the in-plane direction. As illustrated in FIG. 32, the protruding structure QC in one direction (to the right in FIG. 32) along the in-plane direction and the protruding structure QC in the other direction (to the left in FIG. 32) along the in-plane direction may be arranged at a common position in the thickness direction (vertical direction in FIG. 32).

The other configuration of the core substrate 631 is substantially the same as the above-mentioned configuration of the core substrate 601 (FIG. 5: Embodiment 1), so that the same or corresponding components bear the same reference signs, and description thereof is not repeated.

According to the present embodiment, mechanical bonding between the magnetic material portion 300 and each of the first conductor portion 201Q and the second conductor portion 202Q is enhanced by the protruding structure QC. Deterioration of electrical characteristics of the core substrate 631 with temperature cycling is thereby suppressed. The electrical characteristics of the core substrate 631 can thus further be stabilized.

The above-mentioned characteristics of the protruding structure QC regarding the conductor portion may be applied to the other embodiments and modifications thereof described herein.

The above-mentioned embodiments and modifications may freely be combined with each other. While the present invention has been described in detail, the foregoing description is in all aspects illustrative and not restrictive. It is understood that numerous unillustrated modifications can be devised without departing from the scope of the present invention.

What is claimed is:

1. A core substrate with a built-in inductor, the core substrate being for constructing an interposer to which a semiconductor element is mounted, the core substrate comprising:
a ceramic substrate having a first surface, a second surface opposite the first surface in a thickness direction, and a through hole between the first surface and the second surface;
a conductor portion extending through the through hole, and made of a sintered material including sintered metal; and
a magnetic material portion surrounding the conductor portion within the through hole, and made of ceramics, wherein
the ceramic substrate and the magnetic material portion are inorganically bonded together, and the magnetic material portion and the conductor portion are inorganically bonded together.

2. The core substrate according to claim 1, wherein
the conductor portion is a non-hollow body.

3. The core substrate according to claim 1, further comprising
a terminal facing each of the conductor portion and the magnetic material portion in the thickness direction, and made of a sintered material including sintered metal, wherein
the terminal and each of the conductor portion and the magnetic material portion are inorganically bonded together.

4. The core substrate according to claim 1, wherein
the ceramic substrate and the magnetic material portion are bonded together without an organic material interposed therebetween, and the magnetic material portion and the conductor portion are bonded together without an organic material interposed therebetween.

5. The core substrate according to claim 1, wherein
the ceramic substrate and the magnetic material portion are sintered together, and the magnetic material portion and the conductor portion are sintered together.

6. The core substrate according to claim 1, wherein
the magnetic material portion has at least one of a protruding structure toward the ceramic substrate and a step structure facing the ceramic substrate.

7. The core substrate according to claim 1, wherein
the conductor portion has a protruding structure toward the magnetic material portion.

8. An interposer comprising:
the core substrate according to claim 1; and
a wiring portion including a connecting via having a bottom surface connected to the conductor portion of the core substrate, wherein
the bottom surface of the connecting via is separated from the magnetic material portion and the ceramic substrate.

9. The interposer according to claim 8, further comprising
an insulator layer having a via hole in which the connecting via is disposed, wherein
the insulator layer separates the wiring portion and each of the magnetic material portion and the ceramic substrate of the core substrate.

10. The interposer according to claim 9, wherein
the via hole of the insulator layer is tapered toward the conductor portion.

11. The interposer according to claim 9, wherein
the insulator layer contains organic matter.

12. The interposer according to claim 8, wherein
the wiring portion is a plating layer.

13. An interposer comprising:
the core substrate according to claim 1;
an electrode pad connected to the conductor portion of the core substrate; and
a wiring portion including a connecting via having a bottom surface connected to the electrode pad, wherein
the bottom surface of the connecting via is separated from the magnetic material portion and the ceramic substrate.

14. The interposer according to claim 13, wherein
the electrode pad has a portion covering the magnetic material portion.

15. The interposer according to claim 13, wherein
the electrode pad contains silver.

16. The interposer according to claim 13, wherein
the electrode pad is made of a sintered material including sintered metal.

17. The interposer according to claim 13, wherein
the wiring portion is a plating layer.
